(19) United States
(12) Patent Application Publication
(10) Pub. No.: US 2026/0136517 A1
(43) Pub. Date: May 14, 2026

(54) MEMORY CELL AND METHOD FOR MANUFACTURING THE SAME

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/943,244

(22) Filed: Nov. 11, 2024

(51) Int. Cl. H10B 10/00

(52) U.S. Cl. CPC H10B 10/125

(57) ABSTRACT

A method for manufacturing a memory cell is provided. The method includes forming transistors, which forms a first data storage cell, a second data storage cell, and a match cell between the first data storage cell and the second data storage cell; forming a frontside multilayer interconnection structure on front sides of the transistors, wherein the frontside multilayer interconnection structure comprises first to fourth metallization layers; and forming a backside metallization layer on backsides of the transistors, wherein the backside metallization layer comprises a first low power line coupled with at least one of the first data storage cell, the second data storage cell, and the match cell.

### BACKGROUND

Content addressable memories (CAMs) are widely used in applications, for example, where extremely fast search on a database is required, such as in networking, imaging, voice recognition, etc. For example, in network engines, CAMs are used to perform a fast search in the database, corresponding to the header field of any packet, and forward the packet to the corresponding matched address.

Since a very fast search may be required, search performance may be a critical performance parameter for CAMs. Also, the basic mechanism of search may be very power intensive, owing to a parallel nature of operation. Hence, it can be extremely important for a TCAM (Ternary CAM) design to have the best possible search performance along with having the least dynamic power expenditure for the search.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a circuit diagram of a memory cell in accordance with some embodiments of the disclosure.

FIGS. 1B and 1C respectively show a frontside signal placement and a backside signal placement of the memory cell of FIG. 1A in accordance with some embodiments of the disclosure.

FIG. 2A shows a frontside layout of a memory cell of FIG. 1A in accordance with some embodiments of the disclosure.

FIG. 2B shows a frontside metallization layout of a memory cell of FIG. 1A in accordance with some embodiments of the disclosure.

FIG. 2C shows a backside layout of a memory cell of FIG. 1A in accordance with some embodiments of the disclosure.

FIG. 3 shows a frontside-to-backside layout including the frontside layout in FIG. 2A and the backside layout in FIG. 2C.

FIGS. 4-11E illustrate schematic views of intermediate stages in the manufacture of a memory cell in accordance with some embodiments of the present disclosure.

FIG. 12 shows a backside layout of a memory cell of FIG. 1A in accordance with some embodiments of the disclosure.

FIGS. 13A and 13B illustrate cross-sectional views of a memory cell respectively taken along a line X 1-X1 and a line X2-X2 of FIG. 12 in accordance with some embodiments of the present disclosure.

FIGS. 14A and 14B respectively show a frontside layout and a backside layout of a memory cell of FIG. 1A in accordance with some embodiments of the disclosure.

FIGS. 15A and 15B illustrate cross-sectional views of a memory cell respectively taken along a line X1-X1 and a line Y1-Y1 of FIGS. 14A and 14B in accordance with some embodiments of the present disclosure.

FIG. 16 shows a backside layout of a memory cell of FIG. 1A in accordance with some embodiments of the disclosure.

FIGS. 17A and 17B illustrate cross-sectional views of a memory cell respectively taken along a line X1-X1 and a line X2-X2 of FIG. 16 in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

Embodiments disclosed herein will be described with respect to a specific context, namely a memory cell and array, and more particularly, a ternary content addressable memory (TCAM) cell and array. Various modifications are discussed with respect to embodiments; however, other modifications may be made to disclose embodiments while remaining within the scope of the subject matter. A person of ordinary skill in the art will readily understand modifications that may be made.

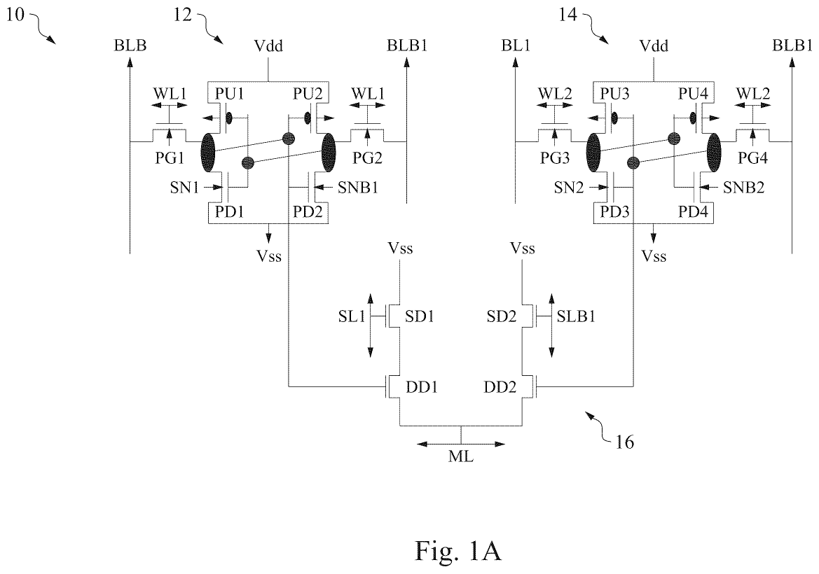

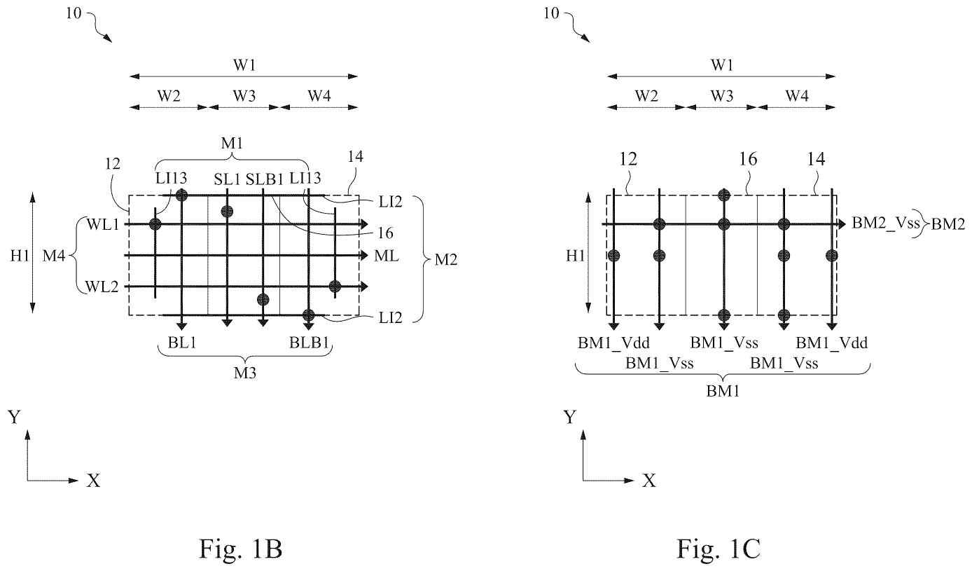

FIG. 1A is a circuit diagram of a memory cell in accordance with some embodiments of the disclosure. The memory cell 10 is a TCAM cell including a first data storage cell 12, a second data storage cell 14, and a match cell 16 between the first data storage cell 12 and the second data storage cell 14.

The first data storage cell 12 includes the pull-up transistors PU1 and PU2, the pull-down transistors PD1 and PD2, and the pass-gate transistors PG1 and PG2. The drains of the pull-up transistor PU1 and the pull-down transistor PD1 are coupled together, and the drains of the pull-up transistor PU2 and the pull-down transistor PD2 are coupled together. The pull-up transistor PU1 and the pull-down transistor PD1 are cross-coupled with the pull-up transistor PU2 and the pull-down transistor PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a first complementary storage node SNB1. Stated differently, the pull-up transistor PU1 and the pull-down transistor PD1 form a first invertor, and the pull-up transistor PU2 and the pull-down transistor PD2 form a second invertor, in which the first inverter is cross-coupled with the second invertor. The sources of the pull-up transistors PU1 and PU2 are coupled to a power voltage Vdd, and the sources of the pull-down transistors PD1 and PD2 are coupled to a ground voltage Vss.

The first storage node SN1 of the first data latch is coupled to a bit line BL1 through the pass-gate transistor PG1, and the first complementary storage node SNB1 is coupled to a complementary bit line BLB1 through the pass-gate transistor PG2. The bit line BL1 and the complementary bit line BLB1 is a bit line pair. The first storage node SN1 and the first complementary storage node SNB1 are complementary nodes that are often at opposite logic levels (logic high or logic low). The gates of the pass-gate transistors PG1 and PG2 are coupled to a first word line WL1.

The second data storage cell 14 includes the pull-up transistors PU3 and PU4, the pull-down transistors PD3 and PD4, and the pass-gate transistors PG3 and PG4. The drains of the pull-up transistor PU3 and the pull-down transistor PD3 are coupled together, and the drains of the pull-up transistor PU4 and the pull-down transistor PD4 are coupled together. the pull-up transistor PU3 and the pull-down transistor PD3 are cross-coupled with the pull-up transistor PU4 and the pull-down transistor PD4 to form a first data latch. The gates of transistors PU4 and PD4 are coupled together and to the drains of transistors PU3 and PD3 to form a second storage node SN2, and the gates of transistors PU3 and PD3 are coupled together and to the drains of transistors PU4 and PD4 to form a second complementary storage node SNB2. Stated differently, the pull-up transistor PU3 and the pull-down transistor PD3 form a third invertor, and the pull-up transistor PU4 and the pull-down transistor PD4 form a fourth invertor, in which the third inverter is cross-coupled with the fourth invertor. The sources of the pull-up transistors PU3 and PU4 are coupled to a power voltage Vdd, and the sources of the pull-down transistors PD3 and PD4 are coupled to a ground voltage Vss.

The second storage node SN2 of the second data latch is coupled to the bit line BL1 through the pass-gate transistor PG3, and the second complementary storage node SNB2 is coupled to the complementary bit line BLB1 through the pass-gate transistor PG4. The second storage node SN2 and the second complementary storage node SNB2 are complementary nodes that are often at opposite logic levels (logic high or logic low). The gates of the pass-gate transistors PG3 and PG4 are coupled to a second word line WL2.

In the memory cell 10, the first data storage cell 12 is a 6 transistors (6-T) SRAM cell accessed by the first word line WL1, the bit line BL1, and the complementary bit line BLB1. Furthermore, the second data storage cell 14 is also a 6-T SRAM cell accessed by the second word line WL2, the bit line BL1, and the complementary bit line BLB2.

The first and second data latches form a storage port of the memory cell 10. The match cell 16 is cascaded from the storage port. The match cell 16 includes the search transistors SD1 and SD2 and the data transistors DD1 and DD2. A source of the search transistor SD1 is coupled to the ground voltage Vss. A drain of the search transistor SD1 is coupled to a source of the data transistor DD1. A drain of the data transistor DD1 is coupled to a match line ML. In other words, the search transistor SD1 and the data transistor DD1 are cascade-coupled between the match line ML and the ground voltage Vss. A gate of the search transistor SD1 is coupled to a search line SL1, and a gate of the data transistor DD1 is coupled to the first storage node SN1. A source of the search transistor SD2 is coupled to the ground voltage Vss. A drain of the search transistor SD2 is coupled to a source of the data transistor DD2. A drain of the data transistor DD2 is coupled to the match line ML. In other words, the search transistor SD2 and the data transistor DD2 are cascade-coupled between the match line ML and the ground voltage Vss. A gate of the search transistor SD2 is coupled to a complementary search line SLB1, and a gate of the data transistor DD2 is coupled to the second complementary storage node SNB2.

The pull-up transistors PU1, PU2, PU3 and PU4 are the p-type transistors. The pull-down transistors PD1, PD2, PD3 and PD4, the pass-gate transistors PG1, PG2, PG3 and PG4, the search transistors SD1 and SD2, and the data transistors DD1 and DD2 are the n-type transistors. The p-type transistors and the n-type transistors are formed by either FinFET transistor or vertically stacked gate-all-around (GAA) horizontal nanosheets transistors. The FinFET transistor may include single-fin or multiple fin. The GAA transistor may include single or multiple vertically stacked nanosheet (or nano-wire, or fork-sheet).

In FIG. 1A, the memory cell 10 has a bit-line pair (e.g., BL1/BLB1) and the word-lines (e.g., WL1 and WL2), the parallel data can be written into the first data storage cell 12 and the second data storage cell 14.

FIGS. 1B and 1C respectively show a frontside signal placement and a backside signal placement of the memory cell of FIG. 1A in accordance with some embodiments of the disclosure. In the memory cell 10, the match cell 16 is disposed between the first data storage cell 12 and the second data storage cell 14 along a direction X. In the memory cell 10, the match cell 16, the first data storage cell 12 and the second data storage cell 14 have the same cell height H1 in a direction Y, which is substantially orthogonal to the direction X. The match cell 16, the first data storage cell 12, and the second data storage cell 14 have the cell widths W2, W3 and W4 in the direction X, respectively. Thus, the memory cell 10 has a cell width W1 in the direction X, in which the cell width W1 may be a sum of the cell widths W2, W3 and W4. In some embodiments, the cell width W2 is equal to the cell width W4. In some embodiments, the cell widths W2 and W4 are greater than the cell width W3.

In FIG. 1B, the first word line WL1, the match line ML and the second word line WL2 extend in the direction X and pass through the first data storage cells 12, the match cells 16, and the second data storage cells 14 of the memory cells 10 in the same row. The bit line BL1 extends in the direction Y and passes through the first data storage cells 12 of the memory cells 10 in the same column. The complementary bit line BLB1 extends in the direction Y and passes through the second data storage cells 14 of the memory cells 10 in the same column. Local connection lines LI13 extend in the direction Y in the first data storage cells 12 and the second data storage cells 14, and respectively electrically coupled with the first word line WL1 and the second word line WL2. Local connection lines LI2 extend in the direction X and pass through the first data storage cells 12, the match cells 16, and the second data storage cells 14 of the memory cells 10 in the same row. One of the local connection lines LI2 is electrically coupled with the bit line BL1, and another one of the local connection lines LI2 is electrically coupled with the complementary bit line BLB1. The search line SL1 and the complementary search line SLB1 extend in the direction Y and pass through the match cells 16 of the memory cells 10 in the same column. In FIG. 1B, a frontside metallization structure includes first to fourth metallization layers M1-M4 stacked one over another on the front side of the transistors. The search line SL1, the complementary search line SLB1, and the local connection lines LI13 are of the first metallization layer M1. The match line ML and the local connection lines LI2 are of the second metallization layer M2. The bit line BL1 and the complementary bit line BLB1 are of the third metallization layer M3. The first word line WL1 and the second word line WL2 are of the fourth metallization layer M4.

In FIG. 1C, a backside metallization structure includes first and second backside metallization layers BM1 and BM2 stacked one over another on the backside side of the transistors. In the present embodiments, the first metallization layer BM1 includes two high power lines BM1_Vdd and three low power lines BM1_Vss. For example, a first one of the high power lines BM1_Vdd and a first one of the low power lines BM1_Vss extend in the direction Y and respectively pass through the first data storage cells 12. A second one of the high power lines BM1_Vdd and a second one of the low power lines BM1_Vss extend in the direction Y and respectively pass through the second data storage cells 14. A third one of the low power lines BM1_Vss extends in the direction Y and passes through the match cells 16. The second backside layer BM2 includes a low power line BM2_Vss electrically coupled with the three low power lines BM1_Vss. The low power line BM2_Vss extends in the direction X and passes through the first data storage cells 12, the match cells 16, and the second data storage cells 14 of the memory cells 10 in the same row.

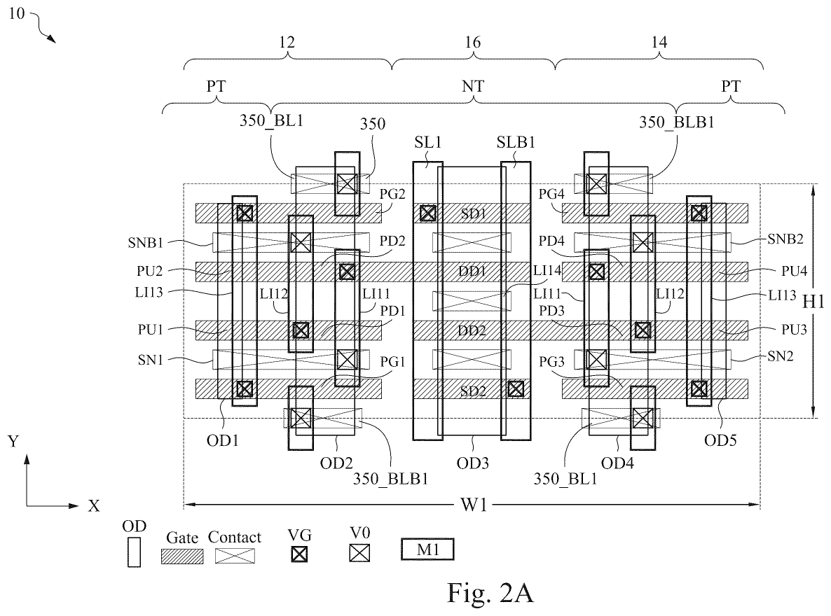

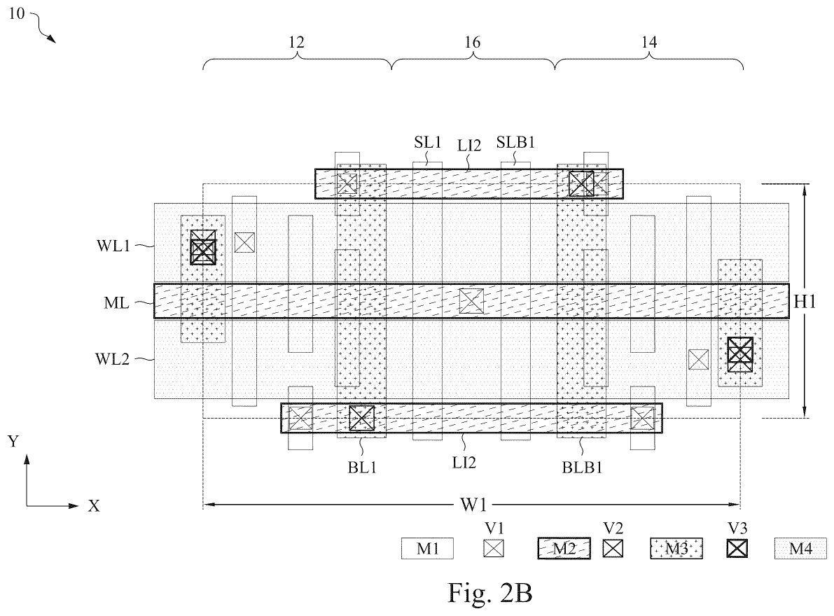

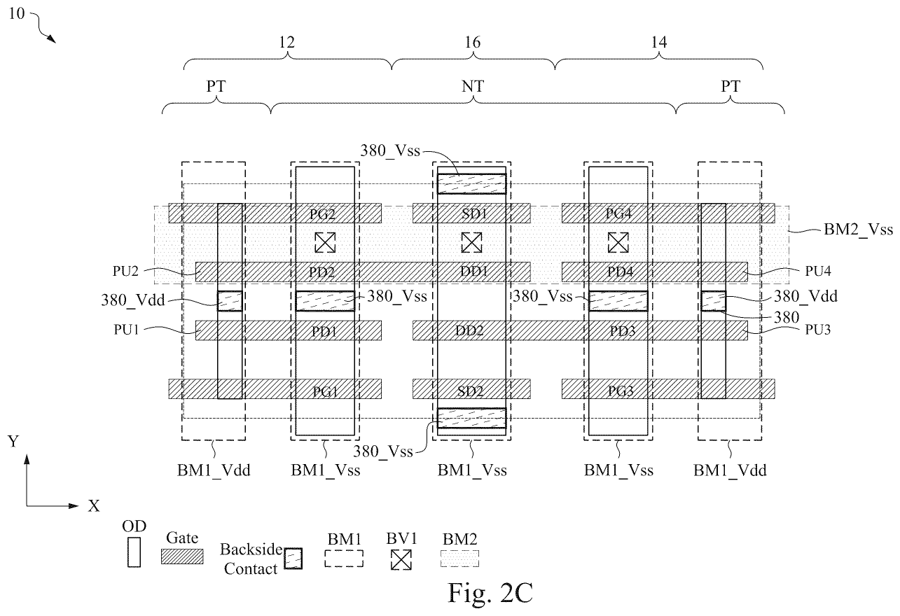

FIG. 2A shows a frontside layout of a memory cell of FIG. 1A in accordance with some embodiments of the disclosure. FIG. 2B shows a frontside metallization layout of a memory cell of FIG. 1A in accordance with some embodiments of the disclosure. FIG. 2C shows a backside layout of a memory cell of FIG. 1A in accordance with some embodiments of the disclosure. All the front-side layouts and the back-side layout are illustrated as being viewed from top/front side.

The memory cell 10 includes a first data storage cell 12, a second data storage cell 14, and a match cell 16. The boundaries of the first data storage cell 12, the second data storage cell 14, and the match cell 16 are indicated by dashed lines. As described above, the memory cell 10 includes a cell height H1 along the Y direction and a cell width W1 along the X direction. In this embodiment, the cell height H1 spans over a total of 4 gate structures and is measured at about 4 gate pitches. Each gate pitch includes a gate length along the direction Y and a gate spacing between two adjacent gate structures along the direction Y.

The first data storage cell 12 includes two active regions OD1 and OD2, the match cell 16 includes one active region OD3, and the second data storage cell 14 includes two active regions OD4 and OD5. The active regions OD1-OD5 extend along the direction Y and spaced apart from each other in a sequence along the direction X orthogonal to the direction Y. The active regions OD1-OD5 can be formed by the nanostructures. The nanostructures may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures include silicon for N-type transistors. In other embodiments, the nanostructures include silicon germanium for P-type transistors. In some embodiments, the nanostructures may also be referred to as channels, channel layers, nanosheets, or nanowires for GAA transistors. With this layout design, in the direction X, the memory cell includes less active regions (lower down to the 5 active regions OD1-OD5), which provides a high capability for cell scaling. The active regions also referred to as oxide-defined region, and denoted as “OD” in the context. In the present embodiments, the active regions OD2-OD4 are in the region NT for NMSOFET, and the active regions OD2-OD4 are in the region PT for PMSOFET.

In the frontside layout shown in FIG. 2A, source/drain contacts 350, denoted as “Contact”, are configured to connect the source/drain regions of the transistors. Source/drain region(s) may be referred to a source or a drain, individually or collectively dependent upon the context. The source/drain contacts 350 may serve as the first storage node SN1, the first complementary storage node SNB1, the second storage node SN2, second complementary storage node SNB2, and nodes 350_BL1 and 350_BLB1 respectively electrically coupled to the bit line BL1 and the complementary bit line BLB1 (referring to FIG. 1A).

The gate structures, denoted as “Gate”, extend in the direction X. In the first data storage cell 12, the gate structures 240 and the active region OD1 form the pull-up transistors PU1 and PU2, and the gate structures 240 and the active region OD2 form the pass-gate transistors PG1 and PG2 and the pull-down transistors PD1 and PD2. In the second data storage cell 14, the gate structures 240 and the active region OD5 form the pull-up transistors PU3 and PU4, and the gate structures 240 and the active region OD4 form the pass-gate transistors PG3 and PG4 and the pull-down transistors PD3 and PD4. In the match cell 16, the gate structures 240 and the active region OD3 form the search transistors SD1 and SD2 and the data transistors DD1 and DD2.

In the frontside layout shown in FIG. 2A, the metal lines of the first metallization layer M1 extend in the direction Y. The metal lines of the first metallization layer M1 includes the search line SL1, the complementary search line SLB1, and the local connection lines LI11-LI14. Gate vias VG are configured to connect the gate structures to the metal lines of the first metallization layer M1. Source/drain vias V0 are configured to connect the source/drain contacts to the metal lines of the first metallization layer M1.

In the frontside layout shown in FIG. 2B, the metal lines of the second metallization layer M2 extend in the direction X, the metal lines of the third metallization layer M3 extend in the direction Y, and the metal lines of the fourth metallization layer M4 extend in the direction X. The metal lines of the second metallization layer M2 includes the match lines ML and the local connection lines LI2. The metal lines of the third metallization layer M3 includes the bit line BL1 and the complementary bit line BLB1. The metal lines of the fourth metallization layer M4 includes the first word line WL1 and the second word line WL2. Metal vias V1 are configured to connect the metal lines of the first metallization layer M1 to the metal lines of the second metallization layer M2. Metal vias V2 are configured to connect the metal lines of the second metallization layer M2 to the metal lines of the third metallization layer M3. Metal vias V3 are configured to connect the metal lines of the third metallization layer M3 to the metal lines of the fourth metallization layer M4.

In the backside layout shown in FIG. 2C, backside source/drain contacts 380, denoted as “Backside Contact”, are configured to connect the source/drain regions of the transistors to metal lines of the backside metallization layer BM1. The backside source/drain contacts 380 may serve as nodes 380_Vdd and 380_Vss respectively electrically coupled to the power voltage Vdd and the ground voltage Vss (referring to FIG. 1A). The metal lines of the first backside metallization layer BM1 extend in the direction X, and the metal lines of the second metallization layer BM2 extend in the direction Y. As aforementioned, the metal lines of the first backside metallization layer BM1 includes the high power lines BM1_Vdd and the low power lines BM1_Vss. The metal lines of the second backside metallization layer BM2 includes the low power line BM2_Vss. Backside metal vias BV1 are configured to connect the metal lines of the first backside metallization layer BM1 to the metal lines of the second backside metallization layer BM2. The memory cell in FIG. 1A can be manufactured by the layouts in FIGS. 2A-2C.

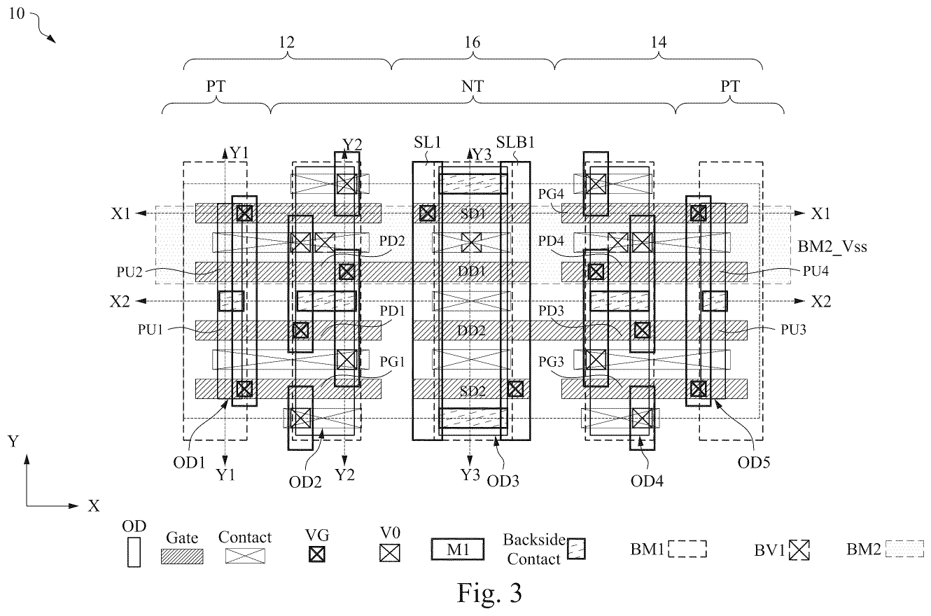

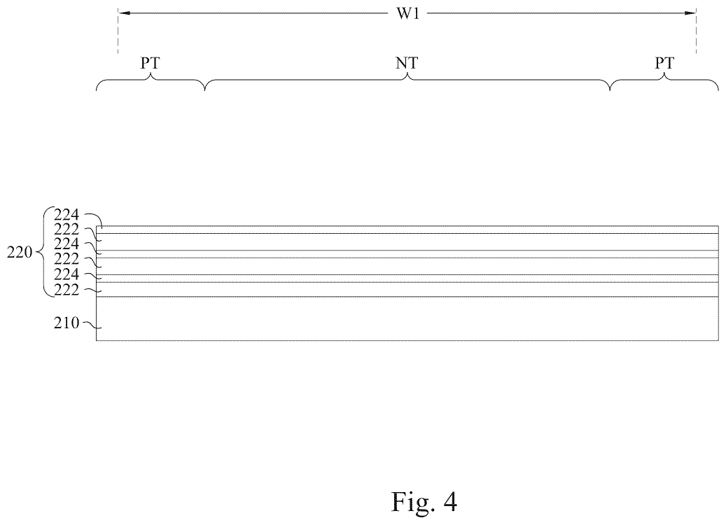

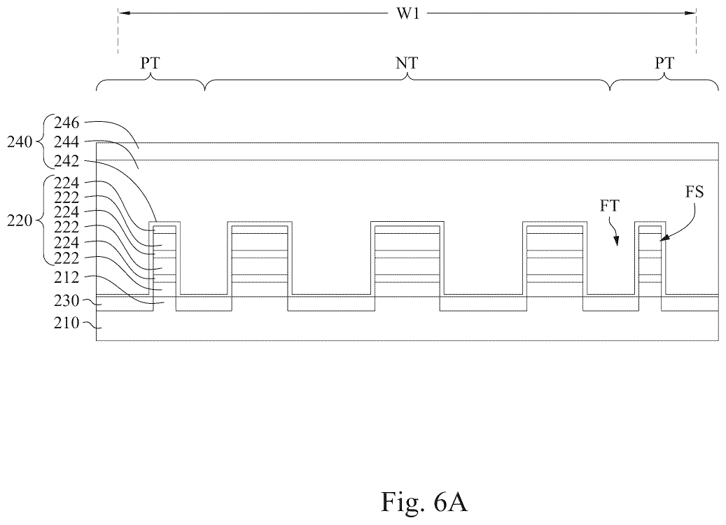

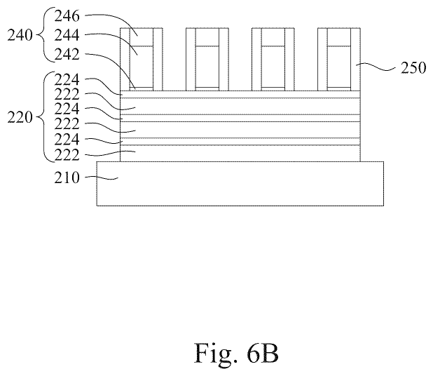

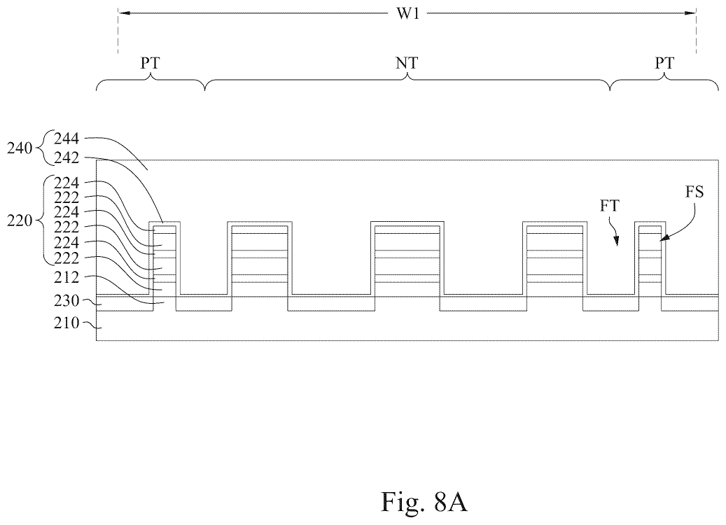

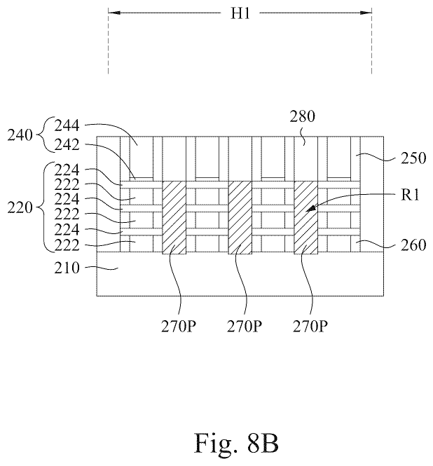

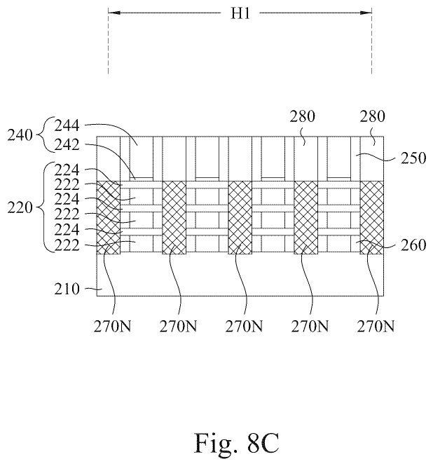

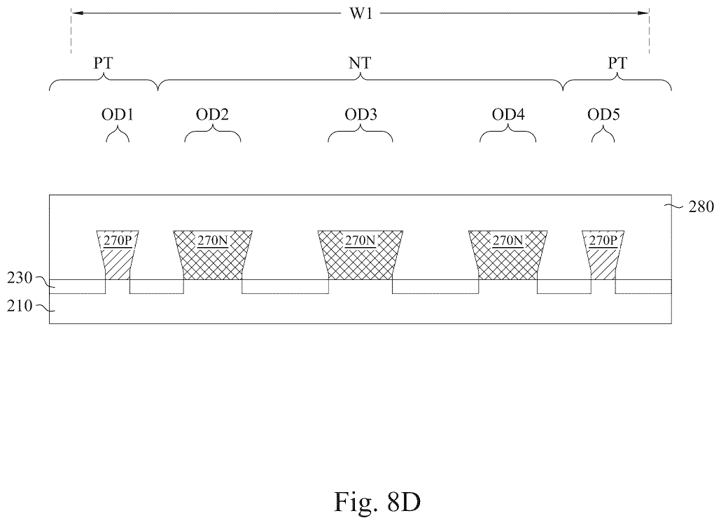

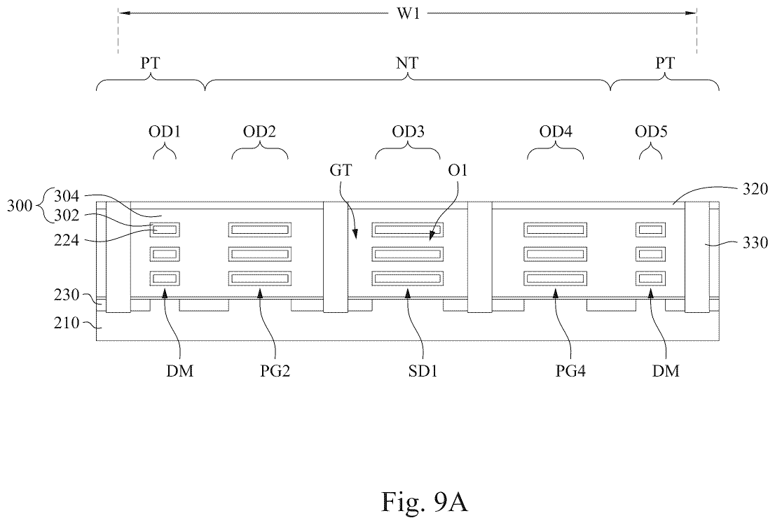

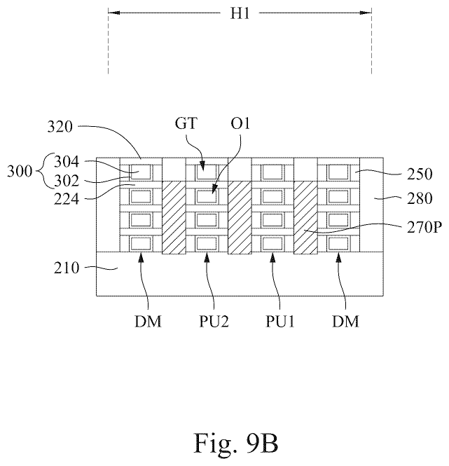

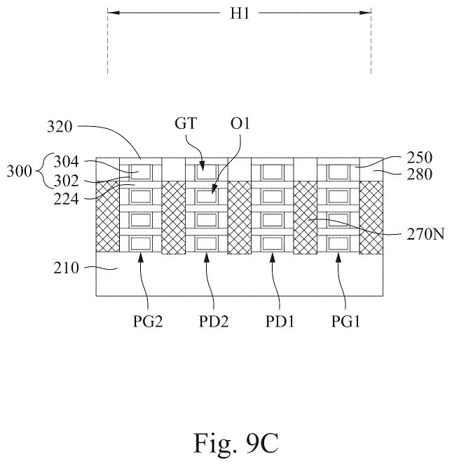

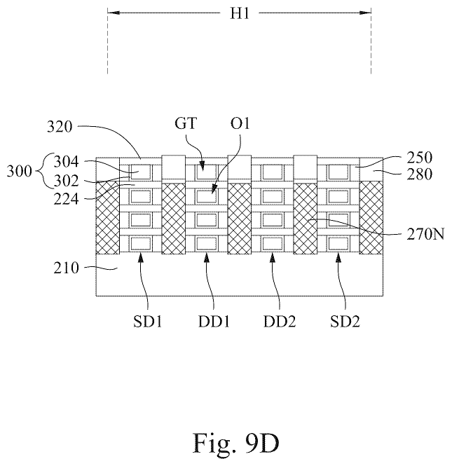

FIG. 3 shows a frontside-to-backside layout including the frontside layout in FIG. 2A and the backside layout in FIG. 2C. FIG. 3 may be considered as a top view of a memory cell of FIG. 1A in accordance with some embodiments of the disclosure. FIGS. 4-11E illustrate schematic views of intermediate stages in the manufacture of a memory cell in accordance with some embodiments of the present disclosure. FIGS. 4, 5, 6A, 8A, 9A, 10A, and 11A illustrate cross-sectional views taken along line X1-X1 in FIG. 3. FIGS. 6B, 7, 8B, 9B, 10B, and 11B illustrate cross-sectional views taken along line Y1-Y1 in FIG. 3. FIGS. 8C, 9C, 10C, and 11C illustrate cross-sectional views taken along line Y2-Y2 in FIG. 3. FIGS. 8D, 10E, and 11E illustrate cross-sectional views taken along line X2-X2 in FIG. 3. FIGS. 9D, 10D, and 11D illustrate cross-sectional views taken along line Y2-Y2 in FIG. 3.

As with the other method embodiments and exemplary devices discussed herein, it is understood that parts of the integrated circuit structure may be fabricated by a CMOS technology process flow, and thus some processes are only briefly described herein. Further, the exemplary integrated circuit structure may include various other devices and features, such as other types of devices such as additional transistors, bipolar junction transistors, resistors, capacitors, inductors, diodes, fuses, static random access memory (SRAM) and/or other logic circuits, etc., but is simplified for a better understanding of the concepts of the present disclosure. In some embodiments, the exemplary integrated circuit structure includes a plurality of semiconductor devices (e.g., transistors), including PFETs, NFETs, etc., which may be interconnected.

Reference is made to FIG. 3 and FIG. 4. An initial structure is provided. The initial structure includes a substrate 210. In some embodiments, the substrate 210 may include silicon (Si). Alternatively, the substrate 210 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 210 may include a semiconductor-on-insulator (SOI) structure. For example, the substrate 210 may include a bulk semiconductor substrate, a buried dielectric layer over the bulk substrate, and a semiconductor layer over the buried dielectric layer. The substrate 210 may include a region NT where n-type devices (e.g., NMOSFET) are to be formed and a region PT where p-type devices (e.g., PMOSFET) are to be formed.

An epitaxial stack 220 is formed over the substrate 210. The epitaxial stack 220 includes epitaxial layers 222 of a first composition interposed by epitaxial layers 224 of a second composition. The first and second compositions can be different. In some embodiments, the epitaxial layers 222 are SiGe and the epitaxial layers 224 are silicon (Si). However, other embodiments are possible including those that provide for a first composition and a second composition having different oxidation rates and/or etch selectivity. In some embodiments, the epitaxial layers 222 include SiGe and where the epitaxial layers 224 include Si, the Si oxidation rate of the epitaxial layers 224 is less than the SiGe oxidation rate of the epitaxial layers 222.

The epitaxial layers 224 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The use of the epitaxial layers 224 to define a channel or channels of a device is further discussed below. It is noted that three layers of the epitaxial layers 222 and three layers of the epitaxial layers 224 are alternately arranged as illustrated in FIG. 4. It can be appreciated that any number of epitaxial layers can be formed in the epitaxial stack 220; the number of layers depending on the desired number of channels regions for the transistor. In some embodiments, the number of the epitaxial layers 224 is between 2 and 10.

As described in more detail below, the epitaxial layers 224 may serve as channel region(s) for a subsequently-formed multi-gate device and the thickness is chosen based on device performance considerations. The epitaxial layers 222 in channel regions(s) may eventually be removed and serve to define a vertical distance between adjacent channel region(s) for a subsequently-formed multi-gate device and the thickness is chosen based on device performance considerations. Accordingly, the epitaxial layers 222 may also be referred to as sacrificial layers, and epitaxial layers 224 may also be referred to as channel layers.

By way of example, epitaxial growth of the layers of the stack 220 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 224 include the same material as the substrate 210. In some embodiments, the epitaxially grown layers 222 and 224 include a different material than the substrate 210. As stated above, in at least some examples, the epitaxial layers 222 include an epitaxially grown silicon germanium (SiGe) layer and the epitaxial layers 224 include an epitaxially grown silicon (Si) layer. Alternatively, in some embodiments, either of the epitaxial layers 222 and 224 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 222 and 224 may be chosen based on providing differing oxidation and/or etching selectivity properties. In some embodiments, the epitaxial layers 222 and 224 are substantially dopant-free (i.e., having an extrinsic dopant concentration from about 0 cm⁻³ to about 1×10¹⁸ cm⁻³), where for example, no intentional doping is performed during the epitaxial growth process.

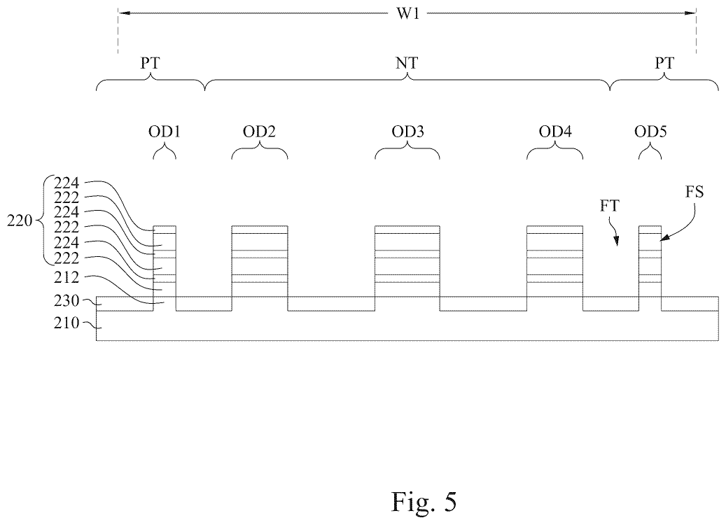

Reference is made to FIG. 3 and FIG. 5. The epitaxial stack 220 and the substrate 210 are patterned, thereby forming plural fins FS. The fins FS may extend along direction X. The patterning may include suitable lithography process and etching processes. The lithography process (e.g., photolithography or e-beam lithography) may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., reactive ion etching), wet etching, and/or other etching methods. In some embodiments, masks are formed over the epitaxial stack 220 by the photolithography process. The masks are used to protect regions of the substrate 210 and the epitaxial stack 220, while etching processes form trenches FT in unprotected regions through the epitaxial stack 220 and into the substrate 210, thereby leaving the plurality of extending fins FS.

In some alternative embodiments, the fins FS may be fabricated using suitable processes including double-patterning or multi-patterning processes. The double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 220. The etching process can include dry etching, wet etching, reactive ion etching (RIE), and/or other suitable processes.

Numerous other embodiments of methods to form the fins on the substrate may also be used including, for example, defining the fin region (e.g., by mask or isolation regions) and epitaxially growing the epitaxial stack 220 in the form of the fins FS. In various embodiments, each of the fins FS includes a base portion 212 patterned from the semiconductor substrate 210 and portions of each of the epitaxial layers 222 and 224 of the epitaxial stack 220.

Isolation structures 230 are formed in the trenches FT between the fins FS. The isolation structures 230 may be referred to as shallow trench isolation (STI) structures. By way of example and not limitation, a dielectric layer is first deposited over the substrate 210, filling the trenches FT with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a sub-atmospheric CVD (SACVD) process, a flowable CVD process, an ALD process, a physical vapor deposition (PVD) process, and/or other suitable processes. In some embodiments, the dielectric layer may include a multi-layer structure, for example, having one or more liner layers. In some embodiments, after deposition of the dielectric layer, the deposited dielectric material is thinned and planarized, for example by a chemical mechanical polishing (CMP) process.

In the layouts, regions between the isolation structures 230 surrounds oxide-defined (OD) regions, which correspond to the fins FS. The isolation (or STI) structures 230 are recessed in an etch back process, such that the OD regions (e.g., fins FS) has exposed sidewall extending above the isolation structures 230. In some embodiments, the recessing process may include a dry etching process, a wet etching process, and/or a combination thereof. In the illustrated embodiments, the etch back process is performed such that each of the epitaxial layers 222 and 224 of the epitaxial stack 220 in the fins FS are exposed.

Reference is made to FIG. 3, FIG. 6A, and FIG. 6B. A dummy gate dielectric layer 242 is then conformally deposited in the trenches FT and over the isolation structures 230. In some embodiments, the dummy gate dielectric layer 242 may include SiO₂, silicon nitride, a high-k dielectric material and/or other suitable material. In various examples, the dummy gate dielectric layer 242 may be deposited by a CVD process, a subatmospheric CVD (SACVD) process, a flowable CVD process, an ALD process, a PVD process, or other suitable process. By way of example, the dummy gate dielectric layer 242 may be used to prevent damages to the fins FS by subsequent processes (e.g., subsequent formation of the dummy gate structures).

Dummy gate structures 240 are formed in accordance with some embodiments of the present disclosure. The dummy gate structures 240 may extend along the direction Y intersecting the direction X that the fins FS extend along. In some embodiments, the dummy gate structures 240 each include the dummy gate dielectric layer 242, a dummy gate electrode layer 244 and a hard mask 246. In some embodiments, the dummy gate structures 260 are formed by various process steps such as layer deposition, patterning, etching, as well as other suitable processing steps. Exemplary layer deposition processes include CVD (including both low-pressure CVD and plasma-enhanced CVD), PVD, ALD, thermal oxidation, e-beam evaporation, or other suitable deposition techniques, or combinations thereof. In forming the gate structures for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

In some embodiments, the dummy gate electrode layer 244 may include polycrystalline silicon (polysilicon). In some embodiments, the hard mask 246 includes an oxide layer such as a pad oxide layer that may include SiO₂, and a nitride layer such as a pad nitride layer that may include Si₃N₄ and/or silicon oxynitride. In some embodiments, after patterning the dummy gate electrode layer 244, exposed portions of the dummy gate dielectric layer 242 not covered under the patterned dummy gate electrode layer 244 are removed from source/drain regions of the fins FS. The etch process may include a wet etch, a dry etch, and/or a combination thereof. The etch process is chosen to selectively etch the dummy gate dielectric layer 242 without substantially etching the fins FS, the dummy gate electrode layer 244 and the hard mask 246.

In some embodiments, gate spacers 250 are formed on sidewalls of the dummy gate structures 240. The gate spacers 250 may include a dielectric material such as SiO2, Si₃N₄, carbon doped oxide, nitrogen doped oxide, porous oxide, or the combination thereof. The gate spacers 250 may include multiple dielectric materials. In some embodiments, the gate spacers 250 may further include air gaps. In some embodiments of formation of the gate spacers 250, a spacer material layer is first deposited over the substrate 210. The spacer material layer may be a conformal layer that is subsequently etched to form gate sidewall spacers on sidewalls of the dummy gate structures 240. In the illustrated embodiments, a spacer material layer is disposed conformally on top and sidewalls of the dummy gate structures 260. By way of example, the spacer material layer may be formed by depositing a dielectric material over the gate structures 240 using processes such as, CVD process, a subatmospheric CVD (SACVD) process, a flowable CVD process, an ALD process, a PVD process, or other suitable process. An anisotropic etching process is then performed on the deposited spacer material layer to expose portions of the fins FS not covered by the dummy gate structures 240 (e.g., in source/drain regions of the fins FS denoted as “S” and “D”). Portions of the spacer material layer directly above the dummy gate structures 240 may be completely removed by this anisotropic etching process. Portions of the spacer material layer on sidewalls of the dummy gate structures 240 may remain, forming gate sidewall spacers, which are denoted as the gate spacers 250, for the sake of simplicity. In some embodiments, a thickness of the gate spacers 250 may be in a range from about 4 nanometers to about 120 nanometers. The gate spacers 250 serve to isolate metal gates from source/drain contacts formed in subsequent processing.

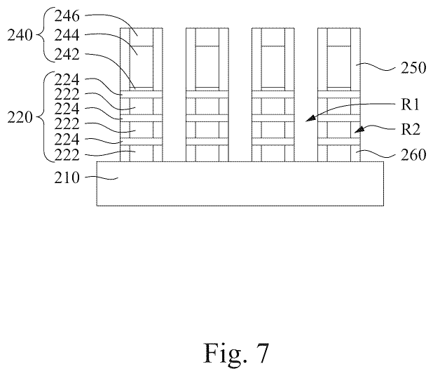

Reference is made to FIG. 3 and FIG. 7. Exposed portions of the semiconductor fins FS that extend laterally beyond the gate spacers 250 (e.g., in source/drain regions S/D of the fins FS) are etched by using, for example, an anisotropic etching process that uses the dummy gate structures 240 and the gate spacers 250 as an etch mask, resulting in recesses R1 into the semiconductor fins FS and between corresponding dummy gate structures 240. In some embodiments, the recesses R1 extends through the channel regions to the substrate 210 for exposing the sacrificial layers 222 and channel layers 224. After the anisotropic etching, end surfaces of the sacrificial layers 222 and channel layers 224 are substantially aligned with respective outermost sidewalls of the gate spacers 250, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

The sacrificial layers 222 may be laterally or horizontally recessed by using suitable etch techniques, resulting in lateral recesses R2 each vertically between corresponding channel layers 224. This step may be performed by using a selective etching process. By way of example and not limitation, the sacrificial layers 222 are SiGe and the channel layers 224 are silicon allowing for the selective etching of the sacrificial layers 222. In some embodiments, the selective wet etching includes an APM etch (e.g., ammonia hydroxide-hydrogen peroxide-water mixture) that etches SiGe at a faster etch rate than it etches Si. In some embodiments, the selective etching includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower than oxidation rate of SiGe, the channel layers 224 remain substantially intact during laterally recessing the sacrificial layers 222. As a result, the channel layers 224 laterally extend past opposite end surfaces of the sacrificial layers 222.

After the sacrificial layers 222 have been laterally recessed, inner spacers 260 are formed in the recesses R2 left by the lateral etching of the sacrificial layers 222. The inner spacers 260 may have a higher k value (or dielectric constant) than that of the gate spacers. For example, the inner spacers 260 includes a suitable dielectric material, such as SiO₂, Si₃N₄, SiON, SiOC, SiOCN, the like, or the combination thereof. In some embodiments, the inner spacers 260 may further include air gaps. Formation of the inner spacers 260 may include depositing an inner spacer material layer is formed to fill the recesses R2. The inner spacer material layer may be deposited by a suitable deposition method, such as ALD. After the deposition of the inner spacer material layer, an anisotropic etching process may be performed to trim the deposited inner spacer material, such that only portions of the deposited inner spacer material that fill the recesses left by the lateral etching of the sacrificial layers 222 are left. After the trimming process, the remaining portions of the deposited inner spacer material are denoted as inner spacers 260.

Reference is made to FIG. 3 and FIGS. 8A-8D. P-type source/drain epitaxial structures 270P and n-type source/drain epitaxial structures 270N are formed in the recesses R1 in the fins FS. In greater detail, the p-type source/drain epitaxial structures 270P are formed in recesses R1 in the active region OD1 and OD5 for PFET devices, and the n-type source/drain epitaxial structures 270N are formed in recesses R1 in the active region OD2-OD4 for NFET devices. In some embodiments, as the recesses R1 extends into the substrate 210, back sides of the epitaxial structure 270P and 270N may be lower than a top surface of the substrate 210. The source/drain epitaxial structures 270P/270N may be formed by performing an epitaxial growth process that provides an epitaxial material on the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the fins FS and the channel layers 224.

The source/drain epitaxial structures 270P may be in-situ doped during the epitaxial process by introducing doping species including: p-type dopants, such as boron. The source/drain epitaxial structures 270N may be in-situ doped during the epitaxial process by introducing doping species including: n-type dopants, such as phosphorus or arsenic. If the source/drain epitaxial structures 270P/270N are not in-situ doped, an implantation process (i.e., a junction implant process) is performed to dope the source/drain epitaxial structures 270P/270N. In some exemplary embodiments, the source/drain epitaxial structures 270N in an NFET device include SiP, SiC, SiPC, SiAs, Si, or combination thereof. The n-type doping concentration of the source/drain epitaxial structures 270N (e.g., phosphorus, arsenic, or both) in the NFET device may be in a range from about 2E19/cm³ to about 3E21/cm³. In some exemplary embodiments, the source/drain epitaxial structures 270P in a PFET device include SiGe doped with boron, or SiGeC doped with boron, Ge doped with boron, Si doped with boron, or combination. The p-type doping concentration of the source/drain epitaxial structures 270P (e.g., boron) in the PFET device may be in a range from about 1E19/cm³ to about 6E20/cm³.

In the present embodiments, the source/drain epitaxial structures 270P/270N are in parallel with the direction Y where the dummy gate structures 240 extends along. The source/drain epitaxial growth from bottom to top may result in top wider shape. For example, each of the source/drain epitaxial structures 270P/270N may have a front-side surface and a back-side surface, and the front-side surface is wider than the back-side surface.

A dielectric material 280 is formed over the substrate 210 and filling the space between the dummy gate structures 240. In some embodiments, the dielectric material 280 includes a contact etch stop layer (CESL) and an interlayer dielectric (ILD) layer formed in sequence. In some examples, the CESL includes a silicon nitride layer, silicon oxide layer, a silicon oxynitride layer, and/or other suitable materials having a different etch selectivity than the ILD layer. The CESL may be formed by plasma-enhanced chemical vapor deposition (PECVD) process and/or other suitable deposition or oxidation processes. The ILD layer is then deposited over the CESL. In some embodiments, the ILD layer includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. The ILD layer may be deposited by a PECVD process or other suitable deposition technique.

After depositing the dielectric material 280, a planarization process may be performed to remove excessive materials of the dielectric material 280. For example, a planarization process includes a chemical mechanical planarization (CMP) process which removes portions of the dielectric material 280 overlying the dummy gate structures 240 and planarizes a top surface of the integrated circuit structure. In some embodiments, the CMP process also removes the hard mask layer 146 in the dummy gate structures 240 (as shown in FIG. 7) and exposes the dummy gate electrode layer 244.

Reference is made to FIG. 3 and FIGS. 9A-9C. Dummy gate structures 240 (referring to FIGS. 8A-8C) are replaced with metal gate structures 300. The metal gate replacement process may include removing the dummy gate structures 240 (referring to FIGS. 8A-8C), and removing the sacrificial layers 222 (referring to FIGS. 8A-8C) therebelow. The removals form gate trenches GT between the gate spacers 250 and openings/spaces O1 between neighboring channel layers 224 and between the bottommost channel layers 224 and the substrate 210. Replacement gate structures 300 are respectively formed in the gate trenches GT and openings/spaces O1 to surround each of the channel layers 224 suspended in the gate trenches GT.

In the illustrated embodiments, the dummy gate structures 240 (referring to FIGS. 8A-8C are removed by using a selective etching process (e.g., selective dry etching, selective wet etching, or a combination thereof) that etches the materials in dummy gate structures 240 (referring to FIGS. 8A-8C) at a faster etch rate than it etches other materials (e.g., gate spacers 250 and the dielectric material 280), thus resulting in gate trenches GT between corresponding gate spacers 250, with the top surface and sidewalls of the fins FS exposed in the gate trenches GT. Subsequently, the sacrificial layers 222 in the gate trenches GT are etched by using another selective etching process that etches the sacrificial layers 222 at a faster etch rate than it etches the channel layers 224, thus forming openings/spaces O1 between neighboring channel layers 224. In this way, the channel layers 224 become nanosheets suspended over the substrate 210 and between the source/drain epitaxial structures 270P/270N. This step is also called a channel release process. In some embodiments, the nanosheets 224 can be interchangeably referred to as nanowires, nanoslabs and nanorings, depending on their geometry. For example, in some other embodiments the channel layers 224 may be trimmed to have a substantial rounded shape (i.e., cylindrical) due to the selective etching process for completely removing the sacrificial layers 222 (referring to FIGS. 8A-8C). In that case, the resultant channel layers 224 can be called nanowires.

In some embodiments, the sacrificial layers 222 (referring to FIGS. 8A-8C) are removed by using a selective wet etching process. In some embodiments, the sacrificial layers 222 (referring to FIGS. 8A-8C) are SiGe and the channel layers 224 are silicon allowing for the selective removal of the sacrificial layers 222 (referring to FIGS. 8A-8C). In some embodiments, the selective wet etching includes an APM etch (e.g., ammonia hydroxide-hydrogen peroxide-water mixture). In some embodiments, the selective removal includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower (sometimes 30 times lower) than oxidation rate of SiGe, the channel layers 224 may remain substantially intact during the channel release process. In some embodiments, both the channel release step and the previous step of laterally recessing sacrificial layers use a selective etching process that etches SiGe at a faster etch rate than etching Si, and therefore these two steps may use the same etchant chemistry in some embodiments. In this case, the etching time/duration of channel release step is longer than the etching time/duration of the previous step of laterally recessing sacrificial layers, so as to completely remove the sacrificial SiGe layers.

The gate structures 300 may be final gates of GAA FETs. The final gate structure may be a high-k/metal gate stack, however other compositions are possible. In some embodiments, each of the gate structures 300 forms the gate associated with the multi-channels provided by the plurality of nanosheets 224. For example, high-k/metal gate structures 300 are formed within the openings O1 provided by the release of nanosheets 224. In various embodiments, the high-k/metal gate structure 300 includes a gate dielectric layer 302 around the nanosheets 224 and a gate metal layer 304 formed around the gate dielectric layer 302 and filling a remainder of gate trenches GT. Formation of the high-k/metal gate structures 300 may include one or more deposition processes to form various gate materials, followed by a CMP processes to remove excessive gate materials. Thus, n-type devices PD1-PD4, PG1-PG4, SD1, SD2, DD1, and DD2 (e.g., NMOSFET), p-type devices PU1-PU4 (e.g., PMOSFET), and dummy devices DM are formed.

Each of the n-type devices PD1-PD4, PG1-PG4, SD1, SD2, DD1, and DD2 (e.g., NMOSFET) may include nanosheets 224 in the region NT, a high-k/metal gate structure 300 surrounding the nanosheets 224, and a pair of the source/drain epitaxial structures 270N on opposite sides of the nanosheets 224. Each of the p-type devices PU1-PU4 (e.g., NMOSFET) may include nanosheets 224 in the region PT, a high-k/metal gate structure 300 surrounding the nanosheets 224, and a pair of the source/drain epitaxial structures 270P on opposite sides of the nanosheets 224. Each of the dummy devices DM may include nanosheets 224 in the region PT, a high-k/metal gate structure 300 surrounding the nanosheets 224, and only one source/drain epitaxial structures 270P on one side of the nanosheets 224.

In some embodiments, the gate dielectric layer 302 includes an interfacial layer formed around the nanosheets 224 and a high-k gate dielectric layer formed around the interfacial layer. The interfacial layer may be silicon oxide formed on exposed surfaces of semiconductor materials in the gate trenches GT by using, for example, thermal oxidation, chemical oxidation, wet oxidation or the like. As a result, surface portions of the nanosheets 224 and the substrate 210 exposed in the gate trenches GT are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 304 includes one or more metal layers. For example, the gate metal layer 304 may include one or more work function metal layers stacked one over another and a fill metal filling up a remainder of gate trenches GT. The one or more work function metal layers in the gate metal layer 304 provide a suitable work function for the high-k/metal gate structures 300. The work function metal layers may include TiN, TaN, TiAl, TiAlN, TaAl, TaAlN, TaAlC, TaCN, WNC, Co, Ni, Pt, W, or combination thereof. NMOSFET and PMOSFET may include the same work function material, or different work function materials. For example, n-type work function metals in the region NT for NMOSFET may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. P-type work function metal in the region PT for PMOSFET may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 304 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. One for more lithography and patterning processes may be performed for forming the work-function metals for NMOSFET and forming the work-function metals for PMOSFET.

After the formation of the metal gate structures 300, top surfaces of the metal gate structure 300 and the gate spacers 250 may be recessed by suitable etching process. The dielectric material 280 may have a higher etch resistance to the etching process than that of the metal gate structures 300 and the gate spacers 250. A top gate dielectric layer 320 may be formed over the recessed top surfaces of the metal gate structures 300 and the gate spacers 250. Formation of the top gate dielectric layer 320 may include depositing suitable dielectric materials over the recessed top surfaces of the metal gate structures 300 and the gate spacers 250, followed by a CMP process. The dielectric material of the top gate dielectric layer 320 may include silicon nitride, silicon carbide, silicon oxynitride, the like, or the combination thereof. Through the configurations, the metal gate structures 300 are capped and protected by the top gate dielectric layer 320. In some alternative embodiments, the top gate dielectric layer 320 can be omitted.

Dielectric plugs 330 may can be disposed between gate structures 300 or at an end of a gate structure 300 after a gate cut process. The dielectric plugs 330 may include suitable dielectric materials, such as oxide, Si₃N₄, other nitride-base dielectric, carbon-base dielectric, high k material (e.g., having a k value equal to or greater than 9), or other suitable dielectric material. Formation of the dielectric plugs 330 may include etching away portions of the metal gate structures 300 and the top gate dielectric layers 320 to expose underlying dielectric materials (e.g., the isolation structures 230), and depositing the suitable gate end dielectric materials over the underlying dielectric materials (e.g., the isolation structures 230). A CMP process may be performed to remove excess portions of the gate end dielectric materials, leaving the remaining portions forming the dielectric plugs 330. Through the configuration, the gate structures 300 can be separated from each other by the dielectric plugs 330.

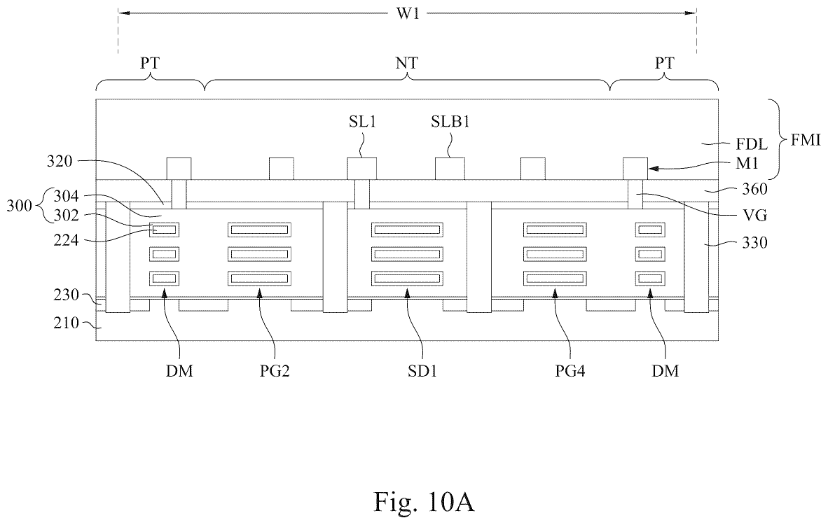

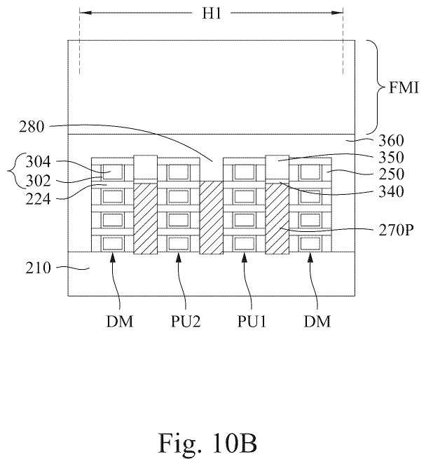

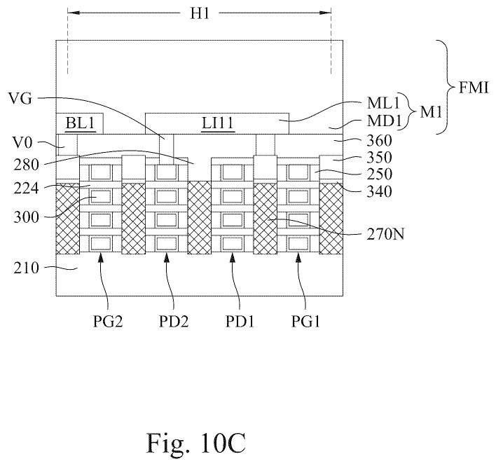

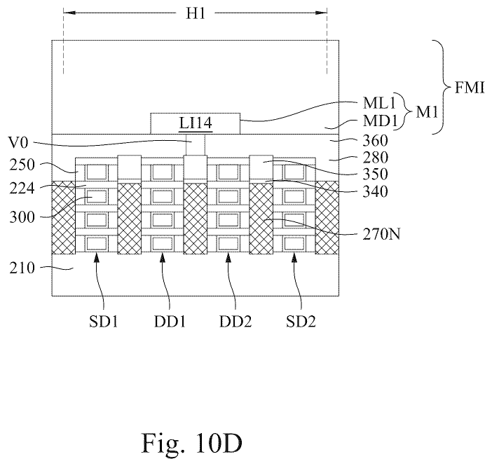

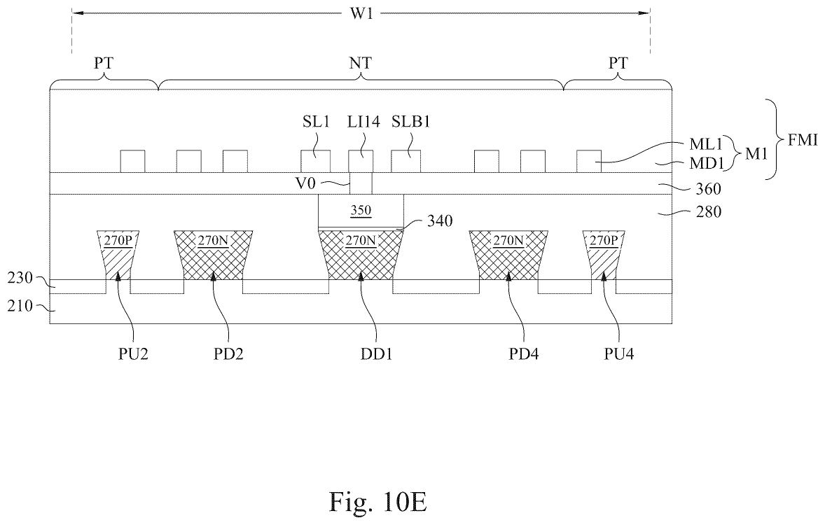

Reference is made to FIG. 3 and FIGS. 10A-10E. Source/drain contacts 350 are formed over front sides of the source/drain epitaxial structures 270P/270N. In some embodiments, the formation of the source/drain contacts 350 includes etching source/drain contact openings through the dielectric material 280 to expose front sides of the source/drain epitaxial structures 270P/270N, and depositing one or more metal materials into the source/drain contact openings. The metal materials may include W, Ru, Co, Cu, Ti, TiN, Ta, TaN, Mo, Ni, Pt, Ir, Rh, the like or combinations thereof. The metal materials are deposited to fill the source/drain contact openings by using suitable deposition techniques (e.g., CVD, PVD, ALD, the like or combinations thereof). Subsequently, a CMP process can be performed to remove excess metal materials outside the source/drain contact openings, while leaving metal materials in the source/drain contact openings to serve as the source/drain contacts 350. The source/drain contacts 350 may include a single metal material or multiple metal material layers. As the front-side surface of source/drain epitaxial structures 270N/270P is wider than the back-side surface of source/drain epitaxial structures 270N/270P, the front-side surface of source/drain epitaxial structures 270N/270P may provide a large area for contact landing, thereby reducing the contact resistance. The source/drain contacts 350 may be isolated from the gate structure 300 by the gate spacers 250. The source/drain contacts 350 may be laterally overlapped with the gate structure 300.

In some embodiments, prior to depositing the metal materials, metal silicide regions 340 may be formed on exposed top surfaces of the source/drain epitaxial structures 270N/270P by using a silicidation process. Silicidation may be formed by blanket depositing a metal layer over the exposed source/drain epitaxial structures 270N/270P, annealing the metal layer such that the metal layer reacts with silicon (and germanium if present) in the source/drain epitaxial structures 270N/270P to form the metal silicide regions 340, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions 340 may be between the source/drain contacts 350 and the source/drain epitaxial structure 270N/270P.

In some embodiments, prior to forming the metal silicide regions 340, one or more extra implantation processes may be performed for increasing a dopant concentration of the source/drain epitaxial structure 270N/270P, thereby lowering the source/drain contact resistance as well as source region resistance. The extra implantation processes may include an n-type implantation using n-type dopants (e.g., phosphorus (P31), arsenic, Ge, or the combination thereof) for NMOSFET, and/or an p-type implantation using n-type dopants (e.g., boron (B11), BF₂, Ge, or the combination thereof) for PMSOFET. One or more implantation masks may be used during the implantation processes. For example, when the n-type implantation is performed to the region NT for NMOSFET, implantation masks are used to cover the region PT for PMSOFET. For example, when the p-type implantation is performed to the region PT for PMOSFET, implantation masks are used to cover the region NT for NMSOFET. The extra implantation processes may further include Ge implantation process. Through the configuration, in the region NT for NMOSFET, the n-type dopant concentration of the source/drain epitaxial structure 270N is higher than the n-type dopant concentration of the source/drain epitaxial structure 270P. Similarly, in a region PT for PMSOFET, the p-type dopant concentration of the source/drain epitaxial structure 270P is higher than the p-type dopant concentration of the source/drain epitaxial structure 270N. After the extra implantations, the metal silicide regions 340 and the source/drain contacts 350 can be formed.

Source/drain vias V0 are formed on the source/drain contacts 350, and gate vias VG are formed on the metal gate structures 300. Prior to the formation of the source/drain vias V0 and the gate via VG, a dielectric layer 360 is deposited over the source/drain contacts 350 and the gate via VG. In some embodiments, the formation of the source/drain vias V0 includes etching openings through the dielectric layer 360 to expose top surfaces of the source/drain contacts 350, and depositing one or more metal materials into the openings. The metal materials may include W, Ru, Co, Cu, Ti, TiN, Ta, TaN, Mo, Ni, Pt, Ir, Rh, the like or combinations thereof. The metal materials are deposited to fill the openings by using suitable deposition techniques (e.g., CVD, PVD, ALD, the like or combinations thereof). Subsequently, a CMP process can be performed to remove excess metal materials outside the openings, while leaving metal materials in the openings to serve as the source/drain vias V0. The source/drain vias V0 may include a single metal material or multiple metal material layers.

In some embodiments, the formation of the gate vias VG includes etching openings through the dielectric layer 360 to expose top surfaces of the metal gate structures 300, and depositing one or more metal materials into the openings. The metal materials may include W, Ru, Co, Cu, Ti, TiN, Ta, TaN, Mo, Ni, Pt, Ir, Rh, the like or combinations thereof. The metal materials are deposited to fill the openings by using suitable deposition techniques (e.g., CVD, PVD, ALD, the like or combinations thereof). Subsequently, a CMP process can be performed to remove excess metal materials outside the openings, while leaving metal materials in the openings to serve as the gate vias VG. The gate vias VG may include a single metal material or multiple metal material layers.

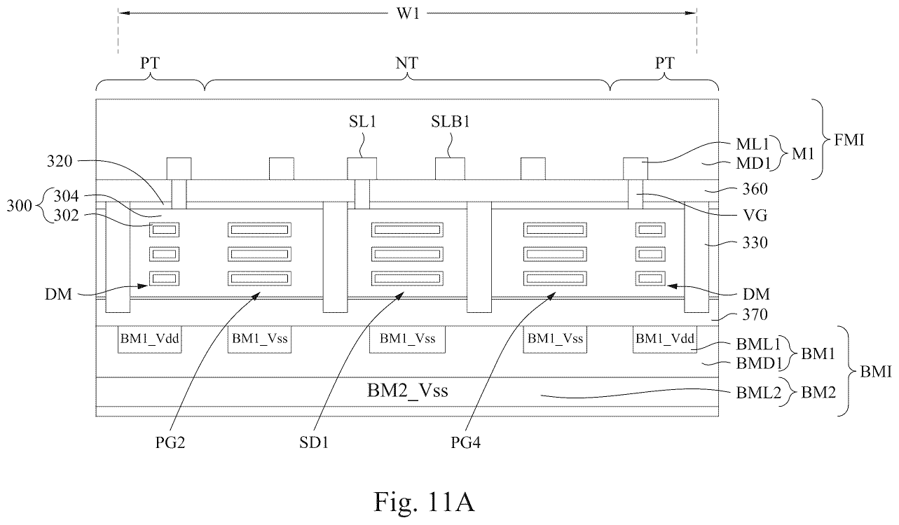

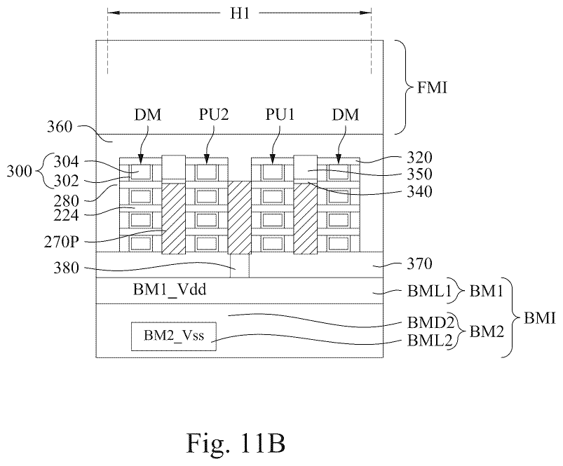

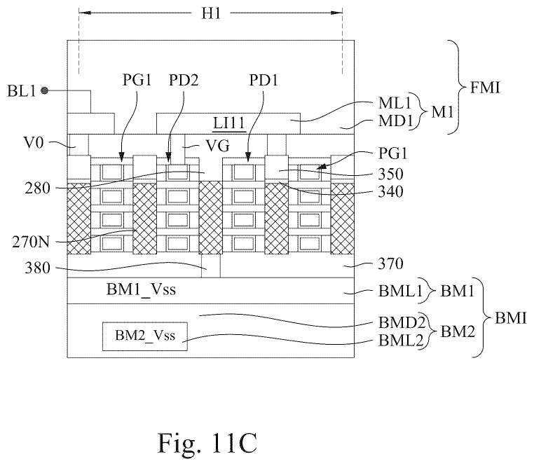

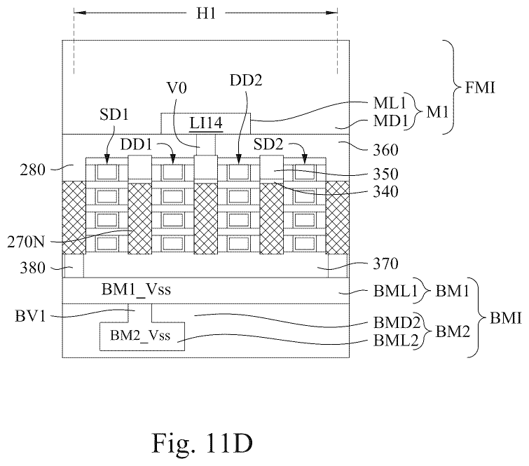

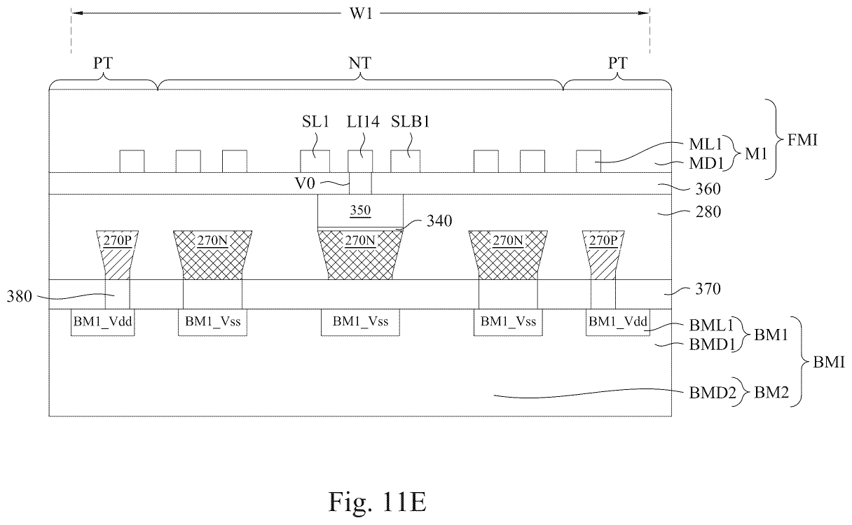

A front-side multilayer interconnection (MLI) structure FMI is formed over the source/drain vias V0 and the gate vias VG, on the front side of the substrate 210. The front-side MLI structure FMI may include at least four front-side metallization layers as the layout shown in FIG. 2B. The number of front-side metallization layers may vary according to design specifications of the integrated circuit structure. Only one front-side metallization layer (e.g., the metallization layer M1) is illustrated in FIG. 3 and FIGS. 11A-11E for the sake of simplicity. The metallization layer M1 is the metallization layer closest to the transistors. The metallization layer M1 may also be referred to as the lowest metallization layer of the front-side MLI structure FMI. The front-side metallization layers each comprise one or more front-side inter-metal dielectric (IMD) layers, one or more horizontal interconnects respectively extending horizontally in the IMD layers, and one or more vertical interconnects respectively extending vertically in the IMD layers. For example, the front-side metallization layer M1 comprises IMD layers MD1 and horizontal interconnects (e.g., metal lines ML1). For example, the metal lines ML1 of the lowest metallization layer M1 of the front-side MLI structure FMI may include the search line SL1, the complementary search line SLB1, and the local connection lines LI11-LI14. The source/drain vias V0 and the gate vias VG are in contact with the metal lines ML1 of the lowest metallization layer M1 to make electrical connection from the metal lines ML1 of the lowest metallization layer M1 to the source/drain epitaxial structure 270P/270B and the metal gate structures 300, respectively.

In some embodiments, as the layout as shown in FIG. 2B, the front-side MLI structure FMI may include may include front-side metallization layer M2-M4 and metal vias V1-V3. The front-side metallization layer M2 is over the front-side metallization layer M1, the front-side metallization layer M3 is over the front-side metallization layer M2, and the front-side metallization layer M4 is over the front-side metallization layer M3. Each of the front-side metallization layer M2-M4 comprises IMD layers and horizontal interconnects (e.g., metal lines). As mentioned previously, the metal line of the second metallization layer M2 includes the match line ML and the local connection lines LI2. The metal lines of the third metallization layer M3 include the bit line BL1 and the complementary bit line BLB1. And, the metal lines of the fourth metallization layer M4 include first word line WL1 and the second word line WL2. And, the metal vias V1 connect the metal lines of the front-side metallization layer M2 to the metal lines ML1, the metal vias V2 connect the metal lines of the front-side metallization layer M3 to the metal lines of the front-side metallization layer M2, and the metal vias V3 connect the metal lines of the front-side metallization layer M4 to the metal lines of the front-side metallization layer M3. In some embodiments, a routing direction of the metal lines of the odd metallization layers M1 and M3 is different from or perpendicular to a routing direction of the even metallization layers M2 and M4. For example, the metal lines of the odd metallization layers M1 and M3 extend along the direction Y, and the metal lines of the even metallization layers M2 and M4 extend along the direction X. The metal vias V1 may be considered as a part of the front-side metallization layer M2 in some embodiments. The metal vias V2 may be considered as a part of the front-side metallization layer M3 in some embodiments. The metal vias V3 may be considered as a part of the front-side metallization layer M4 in some embodiments.

With the gate vias VG, the source/drain vias V0, and the source/drain contacts 350, the gate structure 300 of the pull-down transistor PD2 is electrically coupled with the source/drain epitaxial structure 270N of the pull-down transistor PD1, for example, through the local connection line LI11 of the lowest metallization layer M1. And, with the source/drain vias V0 and the source/drain contacts 350, the source/drain epitaxial structure 270N of the pass-gate transistor PG2, is electrically coupled with the bit line BL1. With the bit line BL1, the gate structure 300 of the search transistor SD1 is electrically coupled with the search line SL1 of the lowest metallization layer M1. With the source/drain vias V0 and the source/drain contacts 350, the source/drain epitaxial structure 270N of the data transistor DD1 and DD2, is electrically coupled with the match line ML, through the local connection line LI14 of the lowest metallization layer M1.

The front-side MLI structure FMI including the metallization layers M1-M4 can be formed using, for example, a single damascene process, a dual damascene process, the like, or combinations thereof. In some embodiments, the IMD layers may include low-k dielectric materials having k values, for example, lower than about 4.0 or even 2.0 disposed between such conductive features. In some embodiments, the IMD layers may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The front-side metal lines and vias may comprise metal materials such as W, Ru, Co, Cu, Ti, TiN, Ta, TaN, Mo, Ni, combinations thereof, or the like. In some embodiments, the front-side metal lines and vias may further comprise one or more barrier/adhesion layers (not shown) to protect the respective front-side IMD layers from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like.

Reference is made to FIG. 3 and FIGS. 11A-11E. Back-side source/drain contacts 380 are formed over back sides of source/drain epitaxial structures 270P/270N. One or more processes are performed to remove materials at the back sides of source/drain epitaxial structures 270P/270N, thereby exposing the back sides of source/drain epitaxial structures 270P/270N. For example, a planarization process (e.g., a CMP process, or a grinding process) is performed to thin down the substrate 210 (referring to the FIGS. 10A-10E). The planarization process may also remove portions of or all the isolation structures 230 (referring to the FIGS. 10A-10E). In some embodiments, after the planarization process, one or more etching process may be performed to remove the substrate 210 and the isolation structures 230 (referring to the FIGS. 10A-10E). In some alternative embodiments, portions of the isolation structures 230 (referring to the FIGS. 10A-10E) may remain at back sides of the devices.

A back-side dielectric layer 370 is deposited over the back sides of the devices, e.g., the back sides of the source/drain epitaxial structures 270P/270N and the back sides of the high-k/metal gate structures 300. In some embodiments, the back-side dielectric layer 370 may include, for example, a low-k dielectric material (with dielectric constant lower than about 7) such as SiO₂, SiN, SiCN, SiOC, SiOCN, the like, or combinations thereof. In some embodiments, the back-side dielectric layer 370 includes a high-k dielectric material such as HfO₂, ZrO₂, HfAlOₓ, HfSiOₓ and Al₂O₃, the like or combinations thereof. A CMP process is may be performed on the back-side dielectric layer 370.

Formation of the back-side source/drain contacts 380 includes etching source/drain contact openings through the back-side dielectric layer 370 to expose back sides of the source/drain epitaxial structures 270P/270N, and depositing one or more metal materials into the source/drain contact openings. The metal materials may include W, Ru, Co, Cu, Ti, TiN, Ta, TaN, Mo, Ni, the like or combinations thereof. The metal materials are deposited to fill the source/drain contact openings by using suitable deposition techniques (e.g., CVD, PVD, ALD, the like or combinations thereof). Subsequently, a CMP process can be performed to remove excess metal materials outside the source/drain contact openings, while leaving metal materials in the source/drain contact openings to serve as the back-side source/drain contacts 380.

In some embodiments, prior to depositing the metal materials, metal silicide regions may be formed on exposed back sides of the source/drain epitaxial structures 270P/270N by using a silicidation process. Silicidation may be formed by blanket depositing a metal layer over the exposed source/drain epitaxial structures 270P/270N, annealing the metal layer such that the metal layer reacts with silicon (and germanium if present) in the source/drain epitaxial structures 270P/270N to form the metal silicide regions, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions may be between the back-side source/drain contacts 380 and the source/drain epitaxial structures 270P/270N.

A back-side multilayer interconnection (MLI) structure BMI is formed over the substrate 210. The back-side MLI structure BMI may include at least two back-side metallization layers. The number of back-side metallization layers may vary according to design specifications of the integrated circuit structure. Only two back-side metallization layers (e.g., the metallization layers BM1 and BM2) are illustrated in FIGS. 11A-11E for the sake of simplicity. The back-side metallization layers each comprise one or more back-side inter-metal dielectric (IMD) layers, one or more horizontal interconnects respectively extending horizontally in the IMD layers, and one or more vertical interconnects respectively extending vertically in the IMD layers. For example, the back-side metallization layer BM1 comprises IMD layers BMD1 and horizontal interconnects (e.g., metal lines BML1). In the present embodiments, the metal lines BML1 of the first metallization layer BM1 may include two high power lines BM1_Vdd and three low power lines BM1_Vss. The metal lines BML1 are in contact with the back-side source/drain contacts 380 to make electrical connection to the source/drain epitaxial structure 270N/270P. And, the back-side metallization layer BM2 comprises IMD layers BMD2 and horizontal interconnects (e.g., metal lines BML2). In the present embodiments, the metal lines BML2 of the first metallization layer BM2 may include low power lines BM2_Vss. Vertical interconnects (e.g., metal via BV1) may disposed between the back-side metallization layers BM1 and BM2 and connect the metal lines BML1 to the metal lines BML2. In some embodiments, a routing direction of the metal lines BML1 is different from or perpendicular to a routing direction of the metal lines BML2. For example, the metal lines BML2 extends along the direction Y, and the metal line BML2 extends along the direction X. The vertical interconnects (e.g., metal via BV1) may be considered as a part of the back-side metallization layer BM2 in some embodiments.

The metallization layers BM1 and BM2 can be formed using, for example, a single damascene process, a dual damascene process, the like, or combinations thereof. In some embodiments, the IMD layers may include low-k dielectric materials having k values, for example, lower than about 4.0 or even 2.0 disposed between such conductive features. In some embodiments, the IMD layers may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The back-side metal lines and vias may comprise metal materials such as W, Ru, Co, Cu, Ti, TiN, Ta, TaN, Mo, Ni, combinations thereof, or the like. In some embodiments, the back-side metal lines and vias may further comprise one or more barrier/adhesion layers (not shown) to protect the respective back-side IMD layers from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like.

In above fabrication process, the formation of the front-side interconnect structure FMI is followed by the formation of the back-side interconnect structure BMI. In the embodiments, prior to the formation of the back-side interconnect structure BMI, a protection layer may be optionally formed over a top surface of the front-side interconnect structure FMI. The protection layer may include one or more suitable layers, such as dielectric layer, a polysilicon layer, or combination thereof. During the formation of the back-side interconnect structure BMI, the protection layer may protect the top surface of the front-side interconnect structure FMI. After the formation of the back-side interconnect structure BMI, the protection layer may be removed.

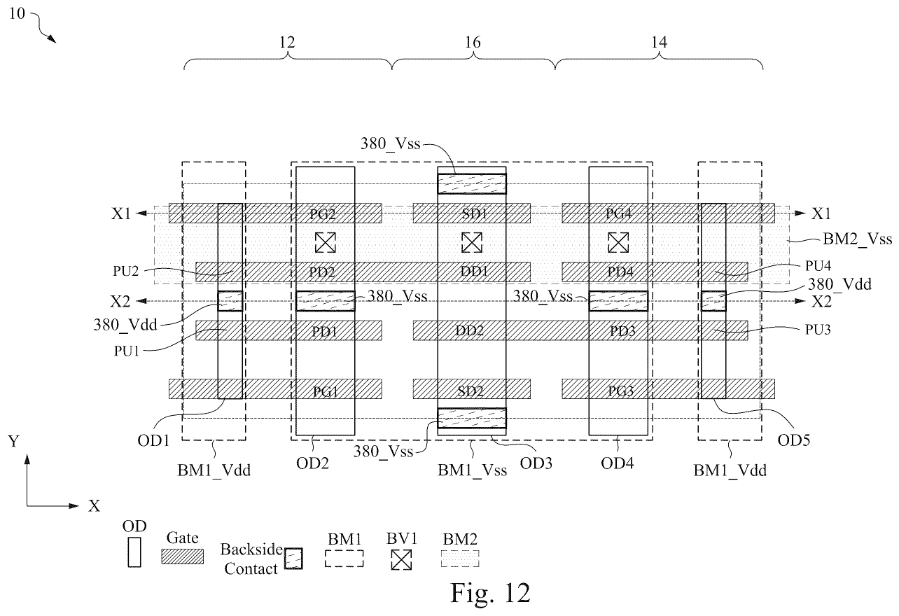

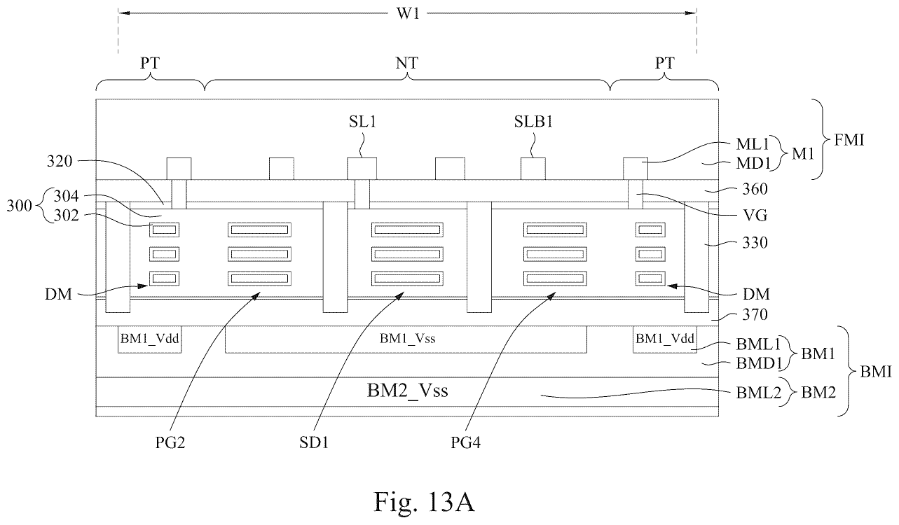

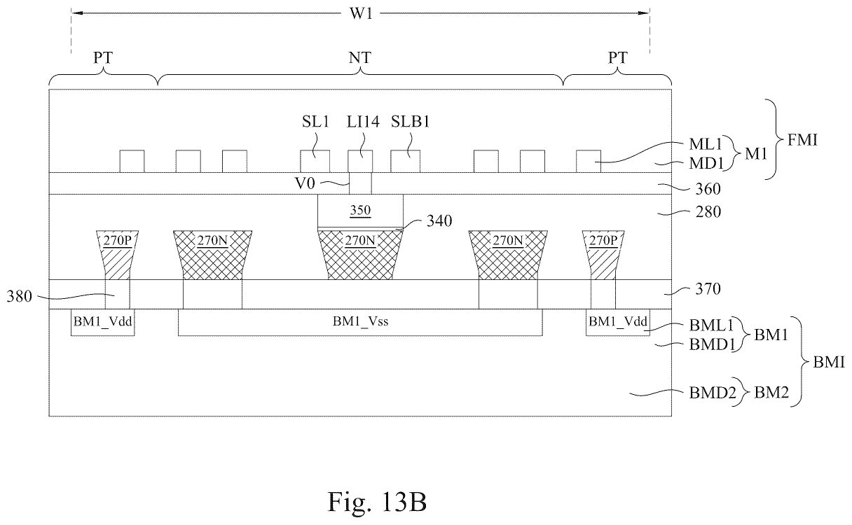

FIG. 12 shows a backside layout of a memory cell of FIG. 1A in accordance with some embodiments of the disclosure. FIGS. 13A and 13B illustrate cross-sectional views of a memory cell respectively taken along a line X1-X1 and a line X2-X2 of FIG. 12 in accordance with some embodiments of the present disclosure. Details of the present embodiments are similar to the embodiments shown in FIGS. 2A-11E, except that the three low power lines BM1_Vss (see FIG. 2C) are merged to one low power line BM1_Vss, in which a width of the low power rail BM1_Vss is much greater than a width of the high power lines BM1_Vdd. Other details of the present embodiments are similar to that of the embodiments shown in FIGS. 2A-11E, and therefore not repeated herein.

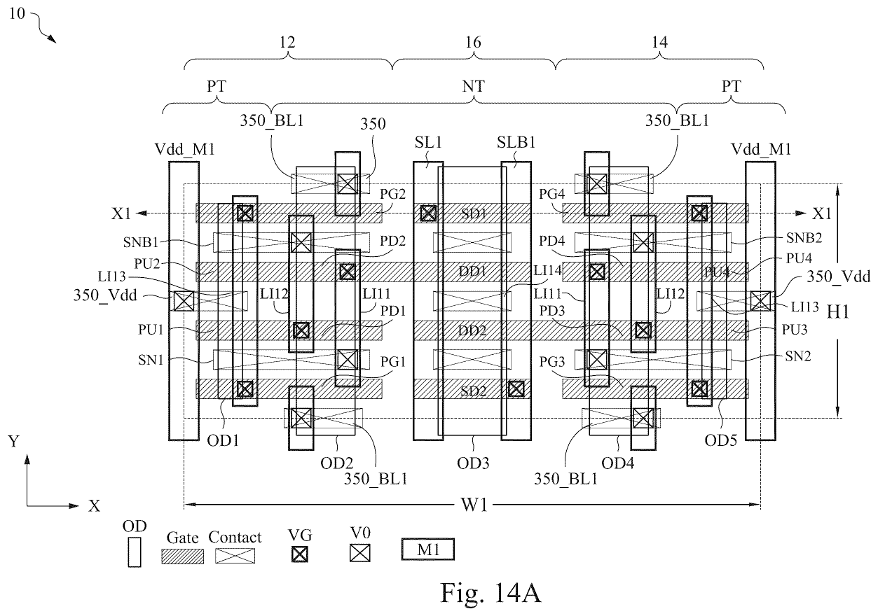

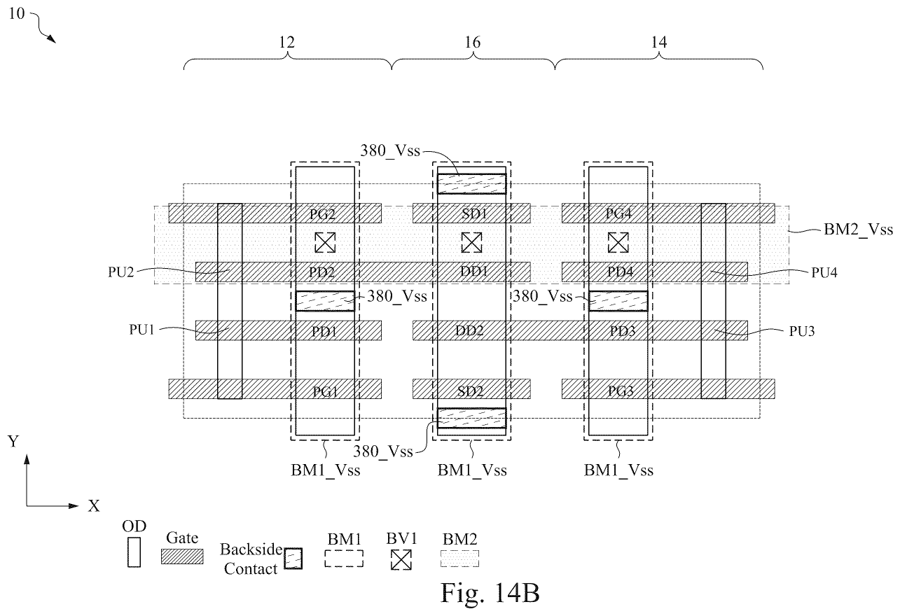

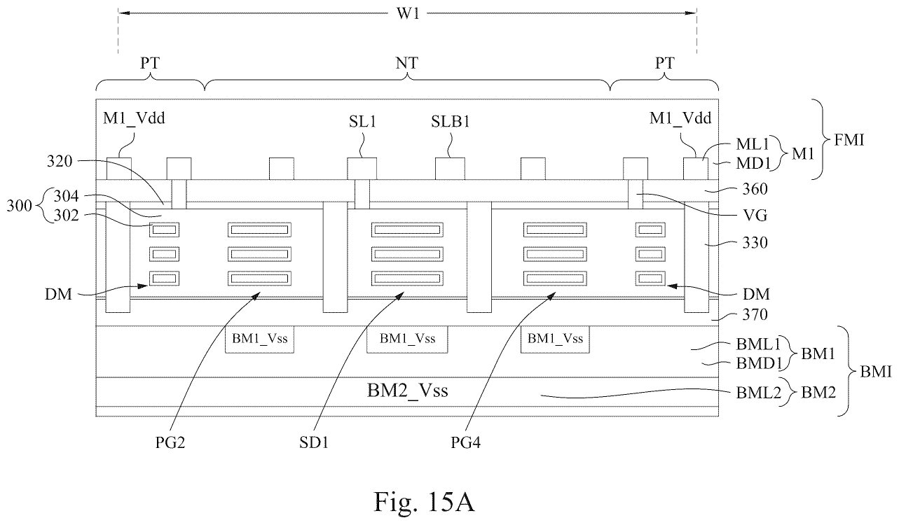

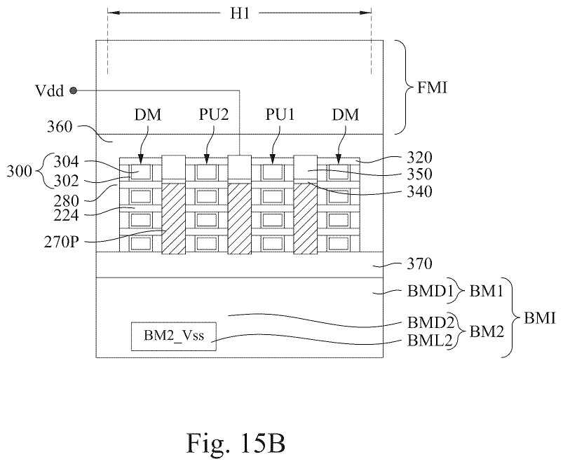

FIGS. 14A and 14B respectively show a frontside layout and a backside layout of a memory cell of FIG. 1A in accordance with some embodiments of the disclosure. FIGS. 15A and 15B illustrate cross-sectional views of a memory cell respectively taken along a line X1-X1 and a line Y1-Y1 of FIGS. 14A and 14B in accordance with some embodiments of the present disclosure. Details of the present embodiments are similar to the embodiments shown in FIGS. 2A-11E, except that the backside high power lines BM1_Vdd are removed from the backside metallization layers BM1, and frontside high power lines M1_Vdd are added to the metallization layers M1. In the present embodiments, one of the source/drain contacts 350 (e.g., the source/drain contact 350 over front sides of the source/drain epitaxial structures 270P of the pull-up transistors PU1 and PU2) may be electrically connected to the frontside high power lines M1_Vdd, thereby achieving the power connection. Other details of the present embodiments are similar to that of the embodiments shown in FIGS. 2A-11E, and therefore not repeated herein.

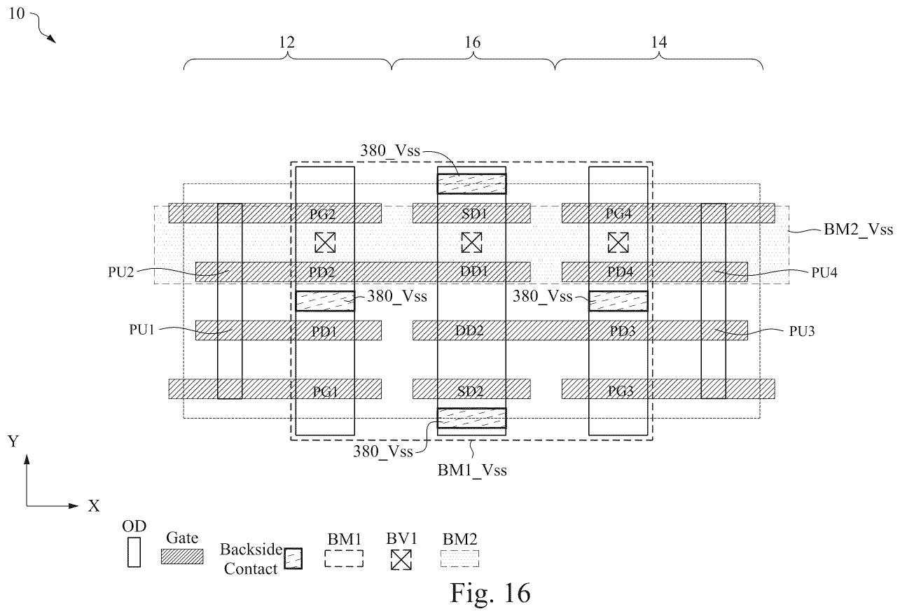

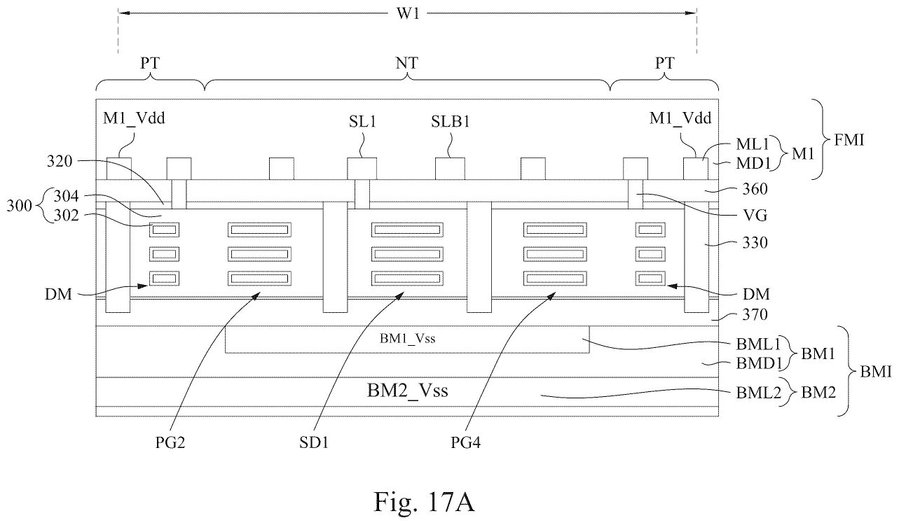

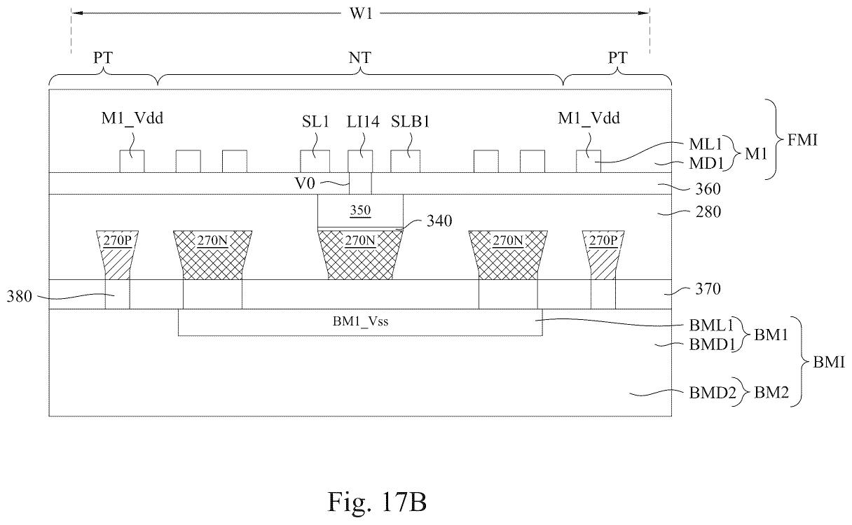

FIG. 16 shows a backside layout of a memory cell of FIG. 1A in accordance with some embodiments of the disclosure. FIGS. 17A and 17B illustrate cross-sectional views of a memory cell respectively taken along a line X1-X1 and a line X2-X2 of FIG. 16 in accordance with some embodiments of the present disclosure. Details of the present embodiments are similar to the embodiments shown in FIGS. 14A and 14B and FIGS. 15A and 15B, except that the three low power lines BM1_Vss (see FIGS. 14B and 15A) are merged to one low power line BM1_Vss. For example, a width of the low power rail BM1_Vss is much greater than a width of the high power lines BM1_Vdd. Other details of the present embodiments are similar to that of the embodiments shown in FIGS. 14A and 14B and 15A and 15B, and therefore not repeated herein.

Based on the above discussions, it can be seen that embodiments of the present disclosure offers advantages. It is understood, however, that other embodiments may offer additional advantages, and not all advantages are necessarily disclosed herein, and that no particular advantage is required for all embodiments. One advantage is that a TCAM cell structure is designed with backside power rails, thereby lowering metal resistance for bit-line conductors by increasing the metal width. Another advantage is that the TCAM cell structure designed with backside power rail can meet both high density (less OD layer and metal lines in each layer) and high speed (lower RC delay for both BL and WL) in SRAM application. Still another advantage is that in cell X-pitch direction, the TCAM cell structure uses less OD lines (lower down to 5 OD lines) to have highly capability for cell scaling. Still another advantage is that the layout is designed with fully symmetry devices for cell stability (device mismatch) improvement. From device mismatch point of view, it prefers to have the same layout (OD/PO/Contact/Metal) environment for cell devices.

According to some embodiments of the present disclosure, a method for manufacturing a memory cell is provided. The method includes forming transistors, wherein the transistors forms a first data storage cell, a second data storage cell, and a match cell between the first data storage cell and the second data storage cell; forming a frontside multilayer interconnection structure on front sides of the transistors, wherein the frontside multilayer interconnection structure comprises: a first metallization layer comprising a search line and a complementary search line coupled with the match cell; a second metallization layer over the first metallization layer, wherein the second metallization layer comprises a match line coupled with the match cell; a third metallization layer over the second metallization layer, wherein the third metallization layer comprises a bit line and a complementary bit line coupled with the first data storage cell and the second data storage cell; and a fourth metallization layer over the third metallization layer, wherein the third metallization layer comprises a first word line coupled with the first data storage cell and a second word line coupled with the second data storage cell; and forming a backside metallization layer on backsides of the transistors, wherein the backside metallization layer comprises a first low power line coupled with at least one of the first data storage cell, the second data storage cell, and the match cell.

According to some embodiments of the present disclosure, a method for manufacturing a memory cell is provided. The method includes forming a first data storage cell, a second data storage cell, and a match cell between the first data storage cell and the second data storage cell, wherein each of the first and second data storage cells comprises: a pull-down transistor; a pull-up transistor; and a pass-gate transistor; and forming a first source/drain contact on a frontside of a source/drain epitaxial structure of the pass-gate transistor of the first data storage cell; forming a bit line coupled with the first source/drain contact; forming a first backside source/drain contact on a backside of a source/drain epitaxial structure of the pull-down transistor of the first data storage cell; and forming a low power line in contact with the first backside source/drain contact.

According to some embodiments of the present disclosure, a method for manufacturing a memory cell is provided. The memory cell includes a first data storage cell, a second data storage cell, a match celf1, a frontside multilayer interconnection structure, and a backside metallization layer. Each of the first and second data storage cells comprises a pull-down transistor, a pull-up transistor, and a pass-gate transistor. The match cell is coupled with a storage node of the first data storage cell and a storage node of the second data storage cell. The match cell is between the first data storage cell and the second data storage cell. The frontside multilayer interconnection structure is on a front side of the pull-down transistor, the pull-up transistor, and the pass-gate transistor, wherein the frontside multilayer interconnection structure comprises a bit line electrically coupled with a source/drain epitaxial structure of the pass-gate transistor of the first data storage cell. The backside metallization layer is on a backside of the pull-down transistor, the pull-up transistor, and the pass-gate transistor. The backside metallization layer comprises a first low power line coupled with a source/drain epitaxial structure of the pull-down transistor of the first data storage cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a memory cell, comprising:
forming a plurality of transistors, wherein the transistors forms a first data storage cell, a second data storage cell, and a match cell between the first data storage cell and the second data storage cell;
forming a frontside multilayer interconnection structure on front sides of the transistors, wherein the frontside multilayer interconnection structure comprises:
a first metallization layer comprising a search line and a complementary search line coupled with the match cell;
a second metallization layer over the first metallization layer, wherein the second metallization layer comprises a match line coupled with the match cell;
a third metallization layer over the second metallization layer, wherein the third metallization layer comprises a bit line and a complementary bit line coupled with the first data storage cell and the second data storage cell; and
a fourth metallization layer over the third metallization layer, wherein the third metallization layer comprises a first word line coupled with the first data storage cell and a second word line coupled with the second data storage cell; and
forming a backside metallization layer on backsides of the transistors, wherein the backside metallization layer comprises a first low power line coupled with at least one of the first data storage cell, the second data storage cell, and the match cell.

2. The method of claim 1, wherein forming the transistors comprises:
forming first to fifth active regions over a semiconductor substrate, wherein the first to fifth active regions extend along a first direction and spaced apart from each other in a sequence along a second direction orthogonal to the first direction;
forming a plurality of n-type epitaxial structures on the second, third, and fourth active regions;
forming a plurality of p-type epitaxial structures on the first and fifth active regions; and
forming a plurality of gate structures on the first to fifth active regions, wherein the first and second active regions form the first data storage cell, the fourth and fifth active regions form the second data storage cell, and the third active region forms the match cell.

3. The method of claim 1, wherein forming the frontside multilayer interconnection structure is performed such that the bit line and the complementary bit line overlaps the first data storage cell and the second data storage cell, respectively.

4. The method of claim 3, wherein forming the frontside multilayer interconnection structure is performed such that the third metallization layer comprises:
a first local connection line coupling the bit line to the second data storage cell; and
a second local connection line coupling the complementary bit line to the first data storage cell.

5. The method of claim 1, wherein forming the first data storage cell, the second data storage cell, and the match cell is performed such that the first data storage cell, the second data storage cell, and the match cell have the same cell height in a direction.

6. The method of claim 1, wherein forming the backside metallization layer is performed such that the first low power line of the backside metallization layer is coupled with the first data storage cell, the second data storage cell, and the match cell.

7. The method of claim 1, wherein forming the backside metallization layer is performed such that the first low power line of the backside metallization layer is coupled with the first data storage cell, and the backside metallization layer further comprises:
a second low power line coupled with the second data storage cell; and
a third low power line coupled with the match cell.

8. The method of claim 1, wherein forming the backside metallization layer is performed such that the backside metallization layer further comprises:
a first high power line coupled with the first data storage cell; and
a second high power line coupled with the second data storage cell.

9. The method of claim 1, wherein forming the frontside multilayer interconnection structure is performed such that the first metallization layer further comprises:
a first high power line coupled with the first data storage cell; and
a second high power line coupled with the second data storage cell.

10. A method for manufacturing a memory cell, comprising:
forming a first data storage cell, a second data storage cell, and a match cell between the first data storage cell and the second data storage cell, wherein each of the first and second data storage cells comprises:
a pull-down transistor;
a pull-up transistor; and
a pass-gate transistor; and
forming a first source/drain contact on a frontside of a source/drain epitaxial structure of the pass-gate transistor of the first data storage cell;
forming a frontside multilayer interconnection structure, wherein the frontside multilayer interconnection structure comprises a bit line electrically coupled with the first source/drain contact;
forming a first backside source/drain contact on a backside of a source/drain epitaxial structure of the pull-down transistor of the first data storage cell; and
forming a low power line in contact with the first backside source/drain contact.

11. The method of claim 10, further comprises:
forming a second backside source/drain contact on a backside of a source/drain epitaxial structure of the pull-up transistor of the first data storage cell; and
forming a high power line in contact with the second backside source/drain contact.

12. The method of claim 10, further comprising:
forming a second source/drain contact on a frontside of a source/drain epitaxial structure of the pull-up transistor of the first data storage cell; and
forming a high power line coupled with the second source/drain contact;

13. The method of claim 10, further comprising:
forming a gate via over a frontside of a gate structure of the pass-gate transistor, wherein forming the frontside multilayer interconnection structure is performed such that the frontside multilayer interconnection structure comprises a word line electrically coupled with the gate via.

14. A memory cell, comprising:
a first data storage cell and a second data storage cell, wherein each of the first and second data storage cells comprises a pull-down transistor, a pull-up transistor, and a pass-gate transistor;
a match cell coupled with a storage node of the first data storage cell and a storage node of the second data storage cell, wherein the match cell is between the first data storage cell and the second data storage cell;
a frontside multilayer interconnection structure on a front side of the pull-down transistor, the pull-up transistor, and the pass-gate transistor, wherein the frontside multilayer interconnection structure comprises a bit line electrically coupled with a source/drain epitaxial structure of the pass-gate transistor of the first data storage cell; and
a backside metallization layer on a backside of the pull-down transistor, the pull-up transistor, and the pass-gate transistor, wherein the backside metallization layer comprises a first low power line coupled with a source/drain epitaxial structure of the pull-down transistor of the first data storage cell.

15. The memory cell of claim 14, wherein the backside metallization layer further comprises a high power line coupled with a source/drain epitaxial structure of the pull-up transistor of the first data storage cell.

16. The memory cell of claim 14, wherein the frontside multilayer interconnection structure further comprises a high power line coupled with a source/drain epitaxial structure of the pull-up transistor of the first data storage cell.

17. The memory cell of claim 14, wherein the first low power line is further coupled with a source/drain epitaxial structure of the pull-down transistor of the second data storage cell.

18. The memory cell of claim 14, wherein the backside metallization layer comprises a second low power line coupled with a source/drain epitaxial structure of the pull-down transistor of the second data storage cell.

19. The memory cell of claim 14, wherein the frontside multilayer interconnection structure further comprises a match line, a search line, and a complementary search line coupled with the match cell.

20. The memory cell of claim 14, further comprising:
a backside source/drain contact on a backside of the source/drain epitaxial structure of the pull-down transistor of the first data storage cell, wherein the first low power line is in contact with the backside source/drain contact.
